(19) United States
(12) Patent Application Publication
(10) Pub. No.: US 2005/0062492 A1
(43) Pub. Date: Mar. 24, 2005

(54) High density integrated circuit apparatus, test probe and methods of use thereof

(76) Inventors: Brian Samuel Beaman, Hyde Park, NY (US); Keith Edward Fogel, Bardonia, NY (US); Paul Alfred Lauro, Nanuet, NY (US); Maurice Heathcote Norcott, Valley Cottage, NY (US); Da-Yuan Shih, Poughkeepsie, NY (US); George Frederick Walker, New York, NY (US)

Correspondence Address: Dr. Daniel P. Morris, Esq.;IBM Corporation, Intellectual Property Law Department, P. O. Box 218, Yorktown Heights, NY, 10598, US

(21) Appl. No.: 10/408,200

(22) Filed: Apr. 4, 2003

Related U.S. Application Data
(62) Division of application No. 09/921,867, filed on Aug. 3, 2001.

(51) Int. Cl. H05K 1/00; G01R 31/02; G01R 31/26

(52) U.S. Cl. 324/765; 174/250; 324/537; 324/754

(57) ABSTRACT

The present invention is directed to a high density test probe which provides a means for testing a high density and high performance integrated circuits in wafer form or as discrete chips. The test probe is formed from a dense array of elongated electrical conductors which are embedded in an compliant or high modulus elastomeric material. A standard packaging substrate, such as a ceramic integrated circuit chip packaging substrate is used to provide a space transformer. Wires are bonded to an array of contact pads on the surface of the space transformer. The space transformer formed from a multilayer integrated circuit chip packaging substrate. The wires are as dense as the contact location array. A mold is disposed surrounding the array of outwardly projecting wires. A liquid elastomer is disposed in the mold to fill the spaces between the wires. The elastomer is cured and the mold is removed, leaving an array of wires disposed in the elastomer and in electrical contact with the space transformer The space transformer can have an array of pins which are on the opposite surface of the space transformer opposite to that on which the elongated conductors are bonded. The pins are inserted into a socket on a second space transformer, such as a printed circuit board to form a probe assembly. Alternatively, an interposer electrical connector can be disposed between the first and second space transformer.

### FIELD OF THE INVENTION

This invention relates to an apparatus and test probe for integrated circuit devices and methods of use thereof.

### BACKGROUND OF THE INVENTION

In the microelectronics industry, before integrated circuit (IC) chips are packaged in an electronic component, such as a computer, they are tested. Testing is essential to determine whether the integrated circuit's electrical characteristics conform to the specifications to which they were designed to ensure that electronic component performs the function for which is was designed.

Testing is an expensive part of the fabrication process of contemporary computing systems. The functionality of every I/O for contemporary integrated circuit must be tested since a failure to achieve the design specification at a single I/O can render an integrated circuit unusable for a specific application. The testing is commonly done both at room temperature and at elevated temperatures to test functionality and at elevated temperatures with forced voltages and currents to burn the chips in and to test the reliability of the integrated circuit to screen out early failures.

Contemporary probes for integrated circuits are expensive to fabricate and are easily damaged. Contemporary test probes are typically fabricated on a support substrate from groups of elongated metal conductors which fan inwardly towards a central location where each conductor has an end which corresponds to a contact location on the integrated circuit chip to be tested. The metal conductors generally cantilever over an aperture in the support substrate. The wires are generally fragile and easily damage and are easily displaceable from the predetermined positions corresponding to the design positions of the contact locations on the integrated circuit being tested. These probes last only a certain number of testing operations, after which they must be replaced by an expensive replacement or reworked to recondition the probes.

FIG. 1 shows a side cross-sectional view of a prior art probe assembly 2 for probing integrated circuit chip 4 which is disposed on surface 6 of support member 8 for integrated circuit chip 4. Probe assembly 2 consists of a dielectric substrate 10 having a central aperture 12 therethrough. On surface 14 of substrate 10 there are disposed a plurality of electrically conducting beams which extend towards edge 18 of aperture 12. Conductors 16 have ends 20 which bend downwardly in a direction generally perpendicular to the plane of surface 14 of substrate 10. Tips 22 of downwardly projecting electrically conducting ends 20 are disposed in electrical contact with contact locations 24 on surface 25 of integrated circuit chip 4. Coaxial cables 26 bring electrical signals, power and ground through electrical connectors 28 at periphery 30 of substrate 10. Structure 2 of FIG. 1 has the disadvantage of being expensive to fabricate and of having fragile inner ends 20 of electrical conductors 16. Ends 20 are easily damaged through use in probing electronic devices. Since the probe 2 is expensive to fabricate, replacement adds a substantial cost to the testing of integrated circuit devices. Conductors 16 were generally made of a high strength metal such as tungsten to resist damage from use. Tungsten has an undesirably high resistivity.

### SUMMARY OF THE INVENTION

It is an object of the present invention to provide an improved high density test probe, test apparatus and method of use thereof.

It is another object of the present invention to provide an improved test probe for testing and burning-in integrated circuits.

It is another object of the present invention to provide an improved test probe and apparatus for testing integrated circuits in wafer form and as discrete integrated circuit chips.

It is an additional object of the present invention to provide probes having contacts which can be designed for high performance functional testing and for high temperature burn in applications.

It is yet another object of the present invention to provide probes having contacts which can be reworked several times by resurfacing some of the materials used to fabricate the probe of the present invention.

It is a further object of the present invention to provide an improved test probe having a probe tip member containing a plurality of elongated conductors each ball bonded to electrical contact locations on space transformation substrate.

A broad aspect of the present invention is a test probe having a plurality of electrically conducting elongated members embedded in a material. One end of each conductor is arranged for alignment with contact locations on a workpiece to be tested.

In a more particular aspect of the present invention, the other end of the elongated conductors are electrically connected to contact locations on the surface of a fan-out substrate. The fan-out substrate provides space transformation of the closely spaced electrical contacts on the first side of the fan-out substrate. Contact locations having a larger spacing are on a second side of the fan out substrate.

In yet another more particular aspect of the present invention, pins are electrically connected to the contact locations on the second surface of the fan out substrate.

In another more particular aspect of the present invention, the plurality of pins on the second surface of the fan-out substrate are inserted into a socket on a second fan-out substrate. The first and second space transformation substrates provide fan out from the fine pitch of the integrated circuit I/O to a larger pitch of electrical contacts for providing signal, power and ground to the workpiece to be tested.

In another more particular aspect of the present invention, the pin and socket assembly is replaced by an interposer containing a plurality of elongated electrical connectors embedded in a layer of material which is squeezed between contact locations on the first fan-out substrate and contact locations on the second fan-out substrate.

In another more particular aspect of the present invention, the test probe is part of a test apparatus and test tool.

Another broad aspect of the present invention is a method of fabricating the probe tip of the probe according to the present invention wherein a plurality of elongated conductors are bonded to contact locations on a substrate surface and project away therefrom.

In a more particular aspect of the method according to the present invention, the elongated conductors are wire bonded to contact locations on the substrate surface. The wires project preferably at a nonorthogonal angle from the contact locations.

In another more particular aspect of the method of the present invention, the wires are bonded to the contact locations on the substrate are embedded in a elastomeric material to form a probe tip for the structure of the present invention.

In another more particular aspect of the present invention, the elongated conductors are embedded in an elastomeric material.

### BRIEF DESCRIPTION OF THE DRAWINGS

FIG. 1 is a schematic cross-section of a conventional test probe for an integrated circuit device.

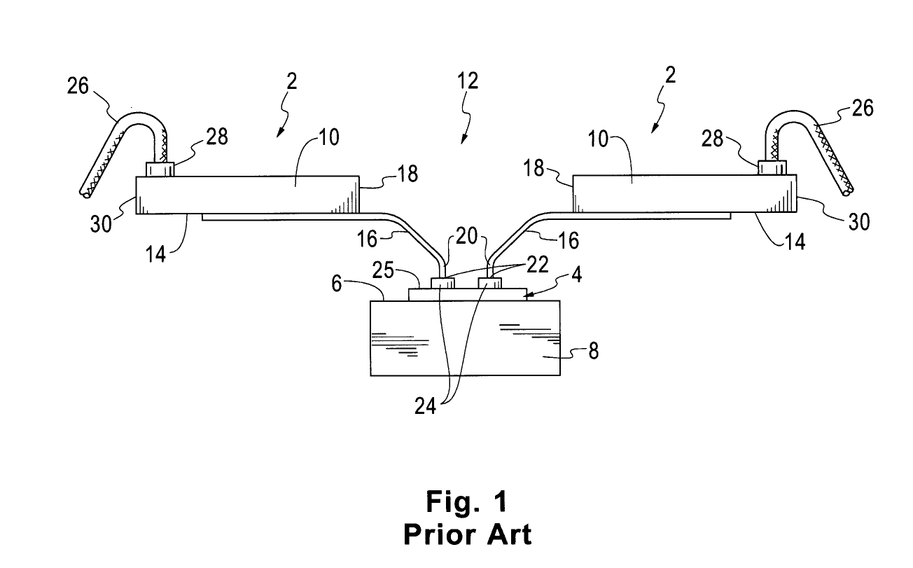

FIG. 2 is a schematic diagram of one embodiment of the probe structure of the present invention.

FIG. 3 is a schematic diagram of another embodiment of the probe structure of the present invention.

FIG. 4 is an enlarged view of an elastomeric connector electrically interconnecting two space transformation substrates of the structure of FIG. 2.

FIG. 5 is an enlarged view of the probe tip within dashed circle 100 of FIGS. 2 or 3.

FIG. 6 shows the probe tip of the structure of FIG. 5 probing an integrated circuit device.

FIGS. 7-13 show the process for making the structure of FIG. 5.

FIG. 14 shows a probe tip structure within a fan-out substrate.

FIG. 15 shows the elongated conductors of the probe tip fixed by solder protuberances to contact locations on a space transformation substrate.

FIG. 16 shows the elongated conductors of the probe tip fixed by laser weld protuberances to contact locations on a space transformation substrate.

FIG. 17 shows both interposer 76 and probe tip 40 rigidly bonded to a space transformer 60.

### DETAILED DESCRIPTION

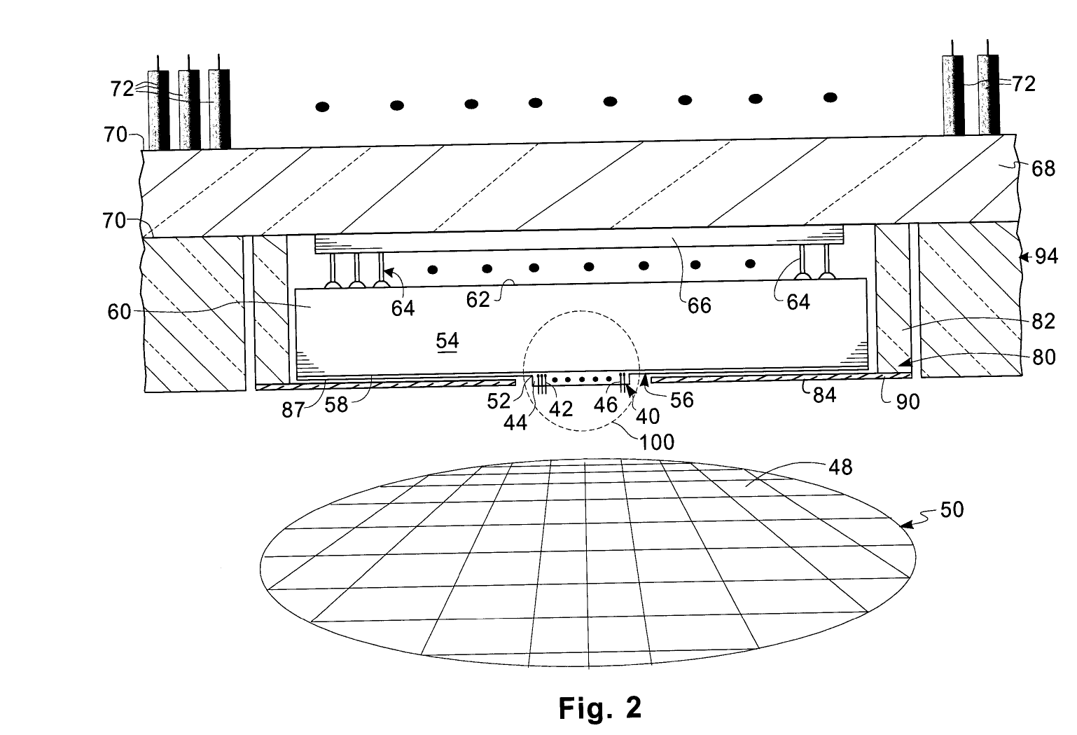

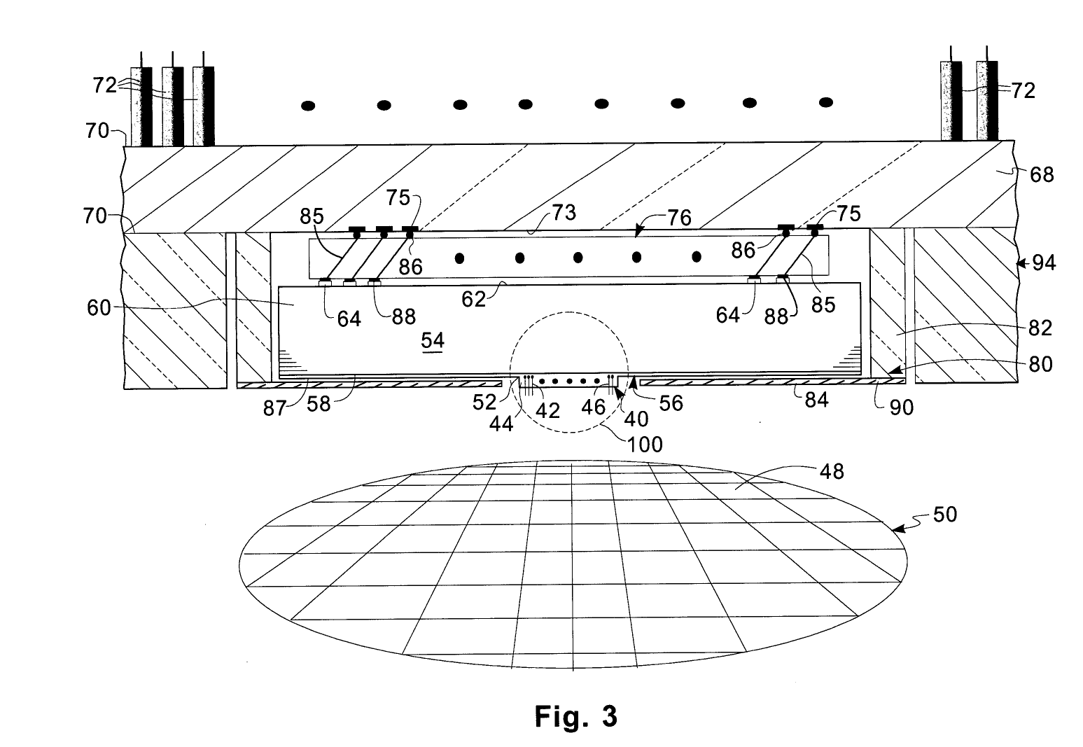

Turning now to the figures, FIGS. 2 and 3 show two embodiments of the test assembly according to the present invention. Numerals common between FIGS. 2 and 3 represent the same thing. Probe head 40 is formed from a plurality of elongated electrically conducting members 42 embedded in a material 44 which is preferably an elastomeric material 44. The elongated conducting members 42 have ends 46 for probing contact locations on integrated circuit devices 48 of wafer 50. In the preferred embodiment, the workpiece is an integrated circuit such as a semiconductor chip or a semiconductor wafer having a plurality of chips. The workpiece can be any other electronic device. The opposite ends 52 of elongated electrical conductors 42 are in electrical contact with space transformer (or fan-out substrate) 54. In the preferred embodiment, space transformer 54 is a multilevel metal/ceramic substrate, a multilevel metal/polymer substrate or a printed circuit board which are typically used as packaging substrates for integrated circuit chips. Space transformer 54 has, in the preferred embodiment, a surface layer 56 comprising a plurality of thin dielectric films, preferably polymer films such as polyimide, and a plurality of layers of electrical conductors, for example, copper conductors. A process for fabricating multilayer structure 56 for disposing it on surface 58 of substrate 60 to form a space transformer 54 is described in U.S. patent application Ser. No. 07/695,368, filed on May 3, 1991, entitled “MULTI-LAYER THIN FILM STRUCTURE AND PARALLEL PROCESSING METHOD FOR FABRICATING SAME” which is assigned to the assignee of the present invention, the teaching of which is incorporated herein by reference. Details of the fabrication of probe head 40 and of the assembly of probe head 40 and 54 will be described herein below.

As shown in FIG. 2, on surface 62 of substrate 60, there are, a plurality of pins 64. Surface 62 is opposite the surface 57 on which probe head 40 is disposed.

Pins 64 are standard pins used on integrated circuit chip packaging substrates. Pins 64 are inserted into socket 66 or plated through-holes in the substrate 68 which is disposed on surface 70 of second space transformer 68. Socket 66 is a type of pin grid array (PGA) socket such as commonly disposed on a printed circuit board of an electronic computer for receiving pins from a packaging substrate. Second space transformer 68 can be any second level integrated circuit packaging substrate, for example, a standard printed circuit board. Socket 66 is disposed on surface 70 of substrate 68. On opposite surface 70 of substrate 68 there are disposed a plurality of electrical connectors to which coaxial cables 72 are electrically connected. Alternatively, socket 68 can be a zero insertion force (ZIF) connector or the socket 68 can be replaced by through-holes in the substrate 68 wherein the through-holes have electrically conductive material surrounding the sidewalls such as a plated through-hole.

In the embodiment of FIG. 3, the pin 64 and socket 66 combination of the embodiment of FIG. 2 is replaced by an interposer, such as, elastomeric connector 76. The structure of elastomeric connector 76 and the process for fabricating elastomeric connector 76 is described in copending U.S. patent application Ser. No. 07/963,364 to B. Beaman et al., filed Oct. 19, 1992, entitled “THREE DIMENSIONAL HIGH PERFORMANCE INTERCONNECTION MEANS”, which is assigned to the assignee of the present invention, the teaching of which is incorporated herein by reference and of which the present application is a continuation-in-part thereof, the priority date of the filing thereof being claimed herein. The elastomeric connected can be opted to have one end permanently bonded to the substrate, thus forming a FRU (field replacement unit) together with the probe/substrate/connector assembly.

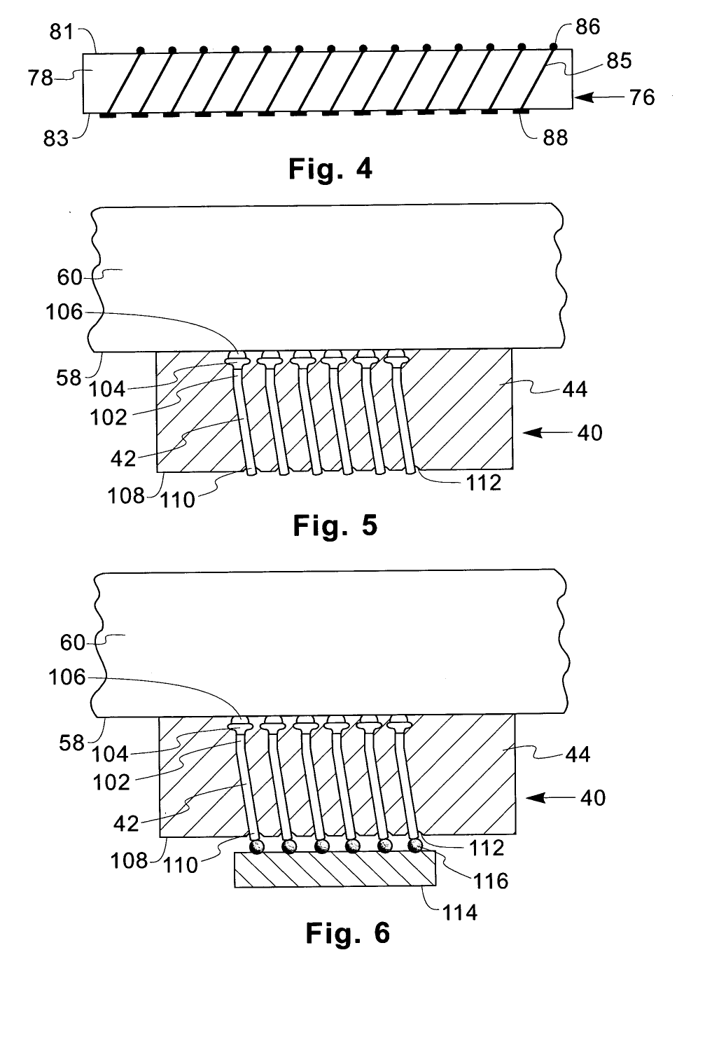

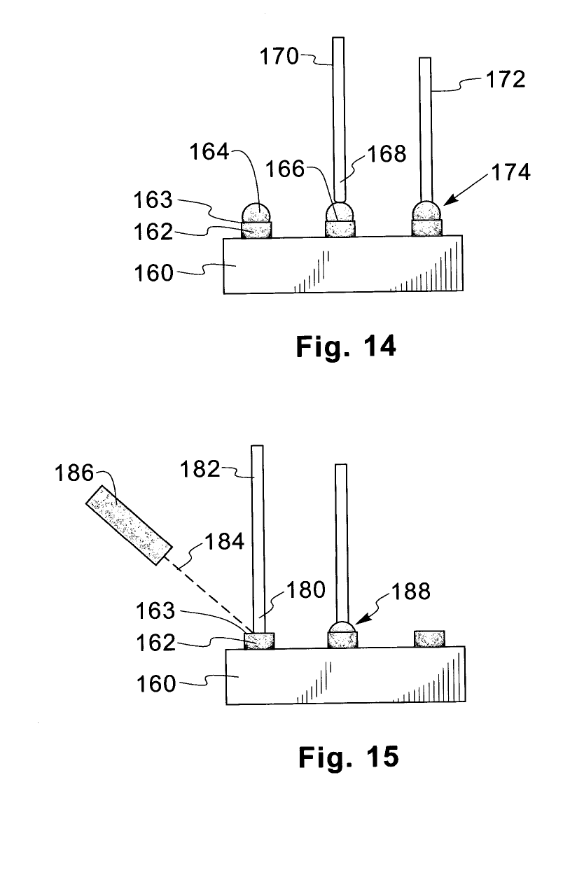

FIG. 4 shows a cross-sectional view of structure of the elastomeric connector 76 of FIG. 3. Connector 76 is fabricated of preferably elastomeric material 78 having opposing, substantially parallel and planar surfaces 80 and 82. Through elastomeric material 78, extending from surface 81 to 83 there are a plurality of elongated electrical conductors 85. Elongated electrical conductors 84 are preferably at a nonorthogonal angle to surfaces 81 and 83. Elongated conductors 85 are preferably wires which have protuberances 86 at surface 81 of elastomeric material layer 78 and flattened protuberances 88 at surface 83 of elastomeric material layer 78. Flattened protuberances 88 preferably have a projection on the flattened surface as shown for the structure of FIG. 14. Protuberance 86 is preferably spherical and flattened protuberance 88 is preferably a flattened sphere. Connector 76 is squeezed between surface 62 of substrate 54 and surface 73 of substrate 68 to provide electrical connection between end 88 of wires 85 and contact location 75 on surface 73 of substrate 68 and between end 88 or wires 85 and contact location 64 on surface 62 of substrate 54.

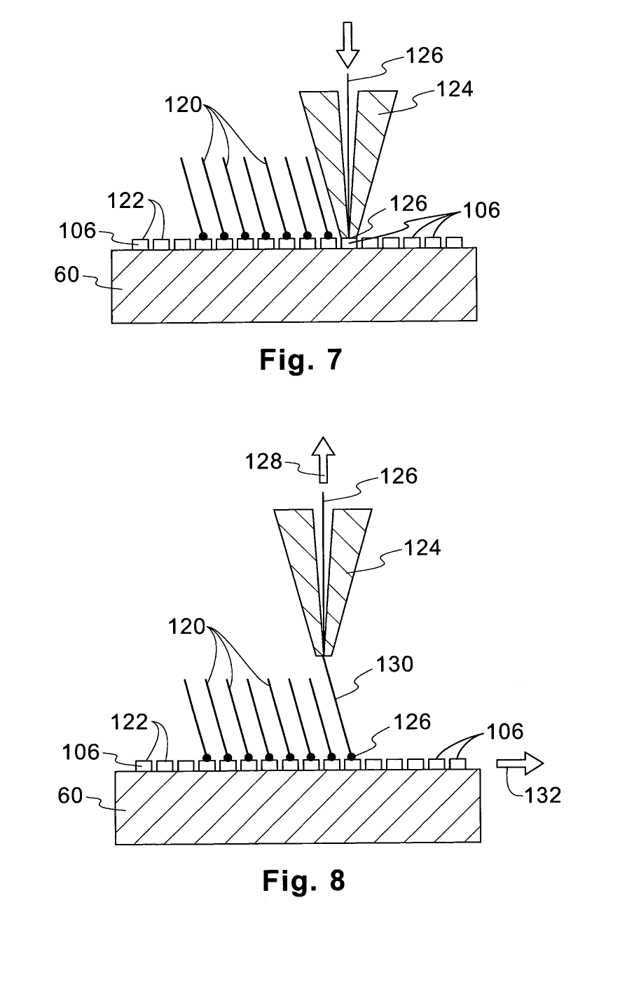

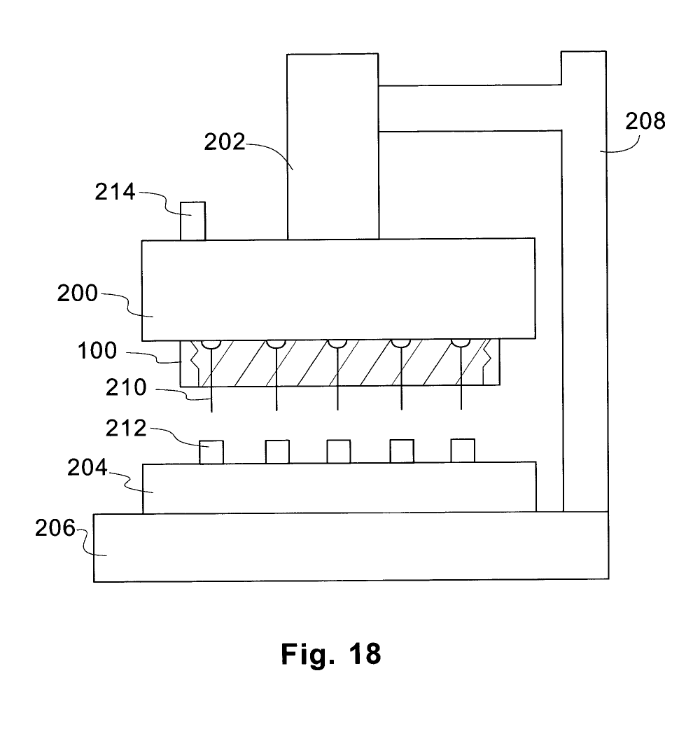

Alternatively, as shown in FIG. 17, connector 76 can be rigidly attached to substrate 54 by solder bonding ends 88 of wires 85 to pads 64 on substrate 54 or by wire bonding ends 86 of wires 85 to pads 64 on substrate 54 in the same manner that wires 42 are bonded to pads 106 as described herein below with respect to FIG. 5. Wires 85 can be encased in an elastomeric material in the same manner as wires 42 of FIG. 5.

Space transformer 54 is held in place with respect to second space transformer 68 by clamping arrangement 80 which is comprised of member 82 which is perpendicularly disposed with respect to surface 70 of second space transformer 68 and member 84 which is preferably parallely disposed with respect to surface 86 of first space transformer 54. Member 84 presses against surface 87 of space transformer 54 to hold space transformer 54 in place with respect surface 70 of space transformer 64. Member 82 of clamping arrangement 80 can be held in place with respect to surface 70 by a screw which is inserted through member 84 at location 90 extending through the center of member 82 and screw into surface 70.

The entire assembly of second space transformer 68 and first space transformer with probe head 40 is held in place with respect wafer 50 by assembly holder 94 which is part of an integrated circuit test tool or apparatus. Members 82, 84 and 90 can be made from materials such as aluminum.

FIG. 5 is a enlarged view of the region of FIGS. 2 or 3 closed in dashed circle 100 which shows the attachment of probe head 40 to substrate 60 of space transformer 54. In the preferred embodiment, elongated conductors 42 are preferably wires which are at a non-orthogonal angle with respect to surface 87 of substrate 60. At end 102 of wire 42 there is preferably a flattened protuberance 104 which is bonded (by wire bonding, solder bonding or any other known bonding technique) to electrically conducting pad 106 on surface 87 of substrate 60. Elastomeric material 44 is substantially flush against surface 87. At substantially oppositely disposed planar surface 108 elongated electrically conducting members 42 have an end 110. In the vicinity of end 110, there is optimally a cavity 112 surrounding end 110. The cavity is at surface 108 in the elastomeric material 44.

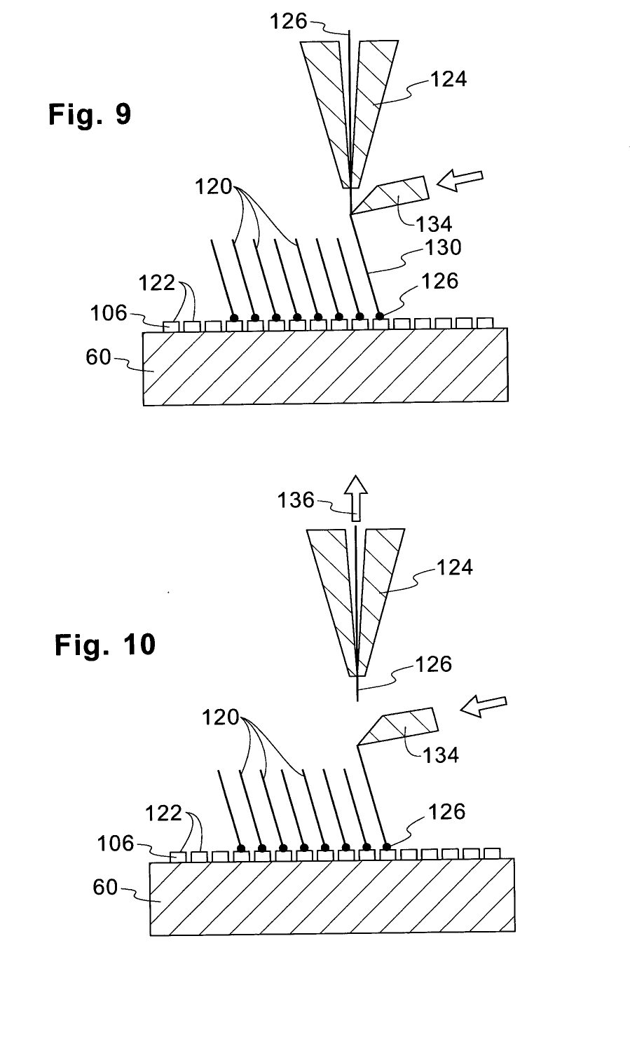

FIG. 6 shows the structure of FIG. 5 used to probe integrated circuit chip 114 which has a plurality of contact locations 116 shown as spheres such as a C4 solder balls. The ends 110 of conductors 42 are pressed in contact with contact locations 116 for the purpose of electrically probing integrated circuit 114. Cavity 112 provides an opening in elastomeric material 44 to permit ends 110 to be pressed towards and into solder mounds 116. Cavity 112 provides a means for solder mounds 116 to self align to ends 110 and provides a means containing solder mounds which may melt, seep or be less viscous when the probe is operated at an elevated temperature. When the probe is used to test or burn-in workpieces have flat pads as contact locations the cavities 112 can remain or be eliminated.

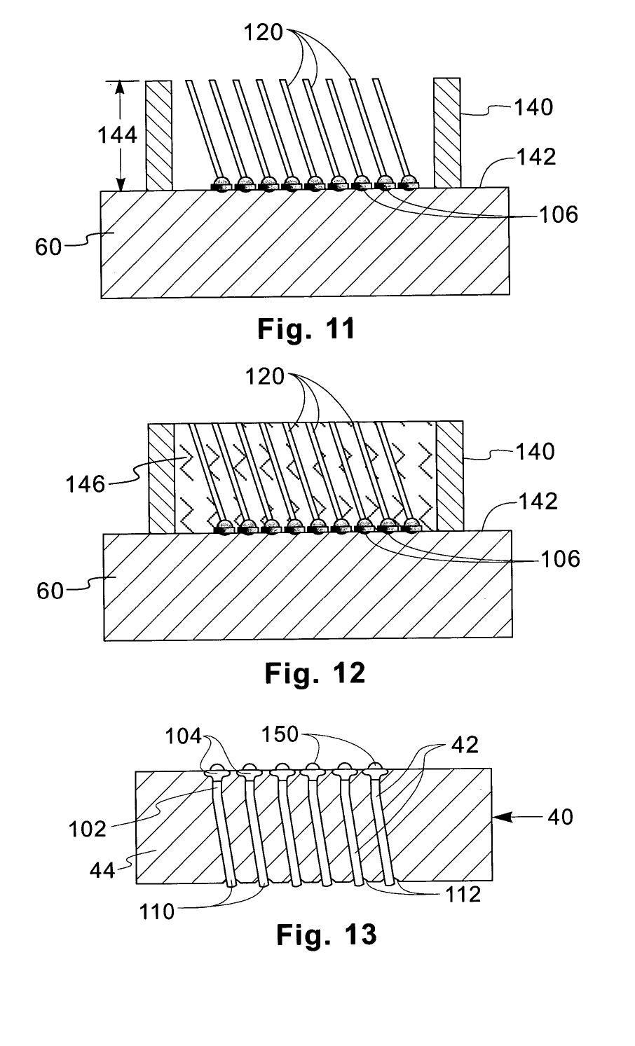

FIGS. 7-13 show the process for fabricating the structure of FIG. 5. Substrate 60 with contact locations 106 thereon is disposed in a wire bound tool. The top surface 122 of pad 106 is coated by a method such as evaporation, sputtering or plating with soft gold or Ni/Au to provide a suitable surface for thermosonic ball bonding. Other bonding techniques can be used such as thermal compression bonding, ultrasonic bonding, laser bonding and the like. A commonly used automatic wire bonder is modified to ball bond gold, gold alloy, copper, copper alloy, aluminum, Pt, nickel or palladium wires 120 to the pad 106 on surface 122 as shown in FIG. 7. The wire preferably has a diameter of 0.001 to 0.005 inches. If a metal other than Au is used, a thin passivation metal such as Au, Cr, Co, Ni or Pd can be coated over the wire by means of electroplating, or electroless plating, sputtering, e-beam evaporation or any other coating techniques known in the industry. Structure 124 of FIG. 7 is the ball bonding head which has a wire 126 being fed from a reservoir of wire as in a conventional wire bonding apparatus. FIG. 7 shows the ball bond head 124 in contact at location 426 with surface 122 of pad 106.

FIG. 8 shows the ball bonding head 124 withdrawn in the direction indicated by arrow 128 from the pad 106 and the wire 126 drawn out to leave disposed on the pad 106 surface 122 wire 130. In the preferred embodiment, the bond head 124 is stationary and the substrate 60 is advanced as indicated by arrow 132. The bond wire is positioned at an angle preferably between 5 to 60° from vertical and then mechanically notched (or nicked) by knife edge 134 as shown in FIG. 9. The knife edge 134 is actuated, the wire 126 is clamped and the bond head 124 is raised. The wire is pulled up and breaks at the notch or nick.

Cutting the wire 130 while it is suspended is not done in conventional wire bonding. In conventional wire bonding, such as that used to fabricate the electrical connector of U.S. Pat. No. 4,998,885, where, as shown in FIG. 8 thereof, one end a wire is ball bonded using a wire bonded to a contact location on a substrate bent over a loop post and the other of the wire is wedge bonded to an adjacent contact location on the substrate. The loop is severed by a laser as shown in FIG. 6 and the ends melted to form balls. This process results in adjacent contact locations having different types of bonds, one a ball bond the other a wedge bond. The spacing of the adjacent pads cannot be less than about ˜20 mils because of the need to bond the wire. This spacing is unacceptable to fabricate a high density probe tip since dense integrated circuits have pad spacing less than this amount. In contradistinction, according to the present invention, each wire is ball bonded to adjacent contact locations which can be spaced less than 5 mils apart. The wire is held tight and knife edge 134 notches the wire leaving upstanding or flying leads 120 bonded to contact locations 106 in a dense array.

When the wire 130 is severed there is left on the surface 122 of pad 106 an angled flying lead 120 which is bonded to surface 122 at one end and the other end projects outwardly away from the surface. A ball can be formed on the end of the wire 130 which is not bonded to surface 122 using a laser or electrical discharge to melt the end of the wire. Techniques for this are described in copending U.S. patent application Ser. No. 07/963,346, filed Oct. 19, 1992, which is incorporated herein by reference above.

FIG. 10 shows the wire 126 notched (or nicked) to leave wire 120 disposed on surface 122 of pad 106. The wire bond head 124 is retracted upwardly as indicated by arrow 136. The wire bond head 124 has a mechanism to grip and release wire 126 so that wire 126 can be tensioned against the shear blade to sever the wire.

After the wire bonding process is completed, a casting mold 140 as shown in FIG. 11 is disposed on surface 142 of substrate 60. The mold is a tubular member of any cross-sectional shape, such as circular and polygonal. The mold is preferably made of metal or organic materials. The length of the mold is preferably the height 144 os the wirse 120. A controlled volume of liquid elastomer 146 is disposed into the casting 140 mold and allowed to settle out (flow between the wires until the surface is level) before curing as shown in FIG. 13. Once the elastomer has cured, the mold is removed to provide the structure shown in FIG. 5 except for cavities 112. The cured elastomer is represented by reference numeral 44. A mold enclosing the wires 120 can be used so that the liquid elastomer can be injection molded to encase the wires 120.

The top surface of the composite polymer/wire block an be mechanically planarized to provide a uniform wire height and smooth polymer surface. A moly mask with holes located over the ends of the wire contacts is used to selectively ablate (or reactive ion etch) a cup shaped recess in the top surface of the polymer around each of the wires. The probe contacts can be reworked by repeating the last two process steps.

A high compliance, high thermal stability siloxane elastomer material is preferable for this application. The compliance of the cured elastomer is selected for the probe application. Where solder mounds are probed a more rigid elastomeric is used so that the probe tips are pushed into the solder mounds where a gold coated aluminum pad is being probed a more compliant elastomeric material is used to permit the wires to flex under pressure so that good electrical contact is made therewith. The high temperature siloxane material is cast or injected and cured similar to other elastomeric materials. To minimize the shrinkage, the elastomer is preferably cured at lower temperature (T≦60°) followed by complete cure at higher temperatures (T≧80°).

Among the many commercially available elastomers, such as ECCOSIL and SYLGARD, the use of polydimethylsiloxane based rubbers best satisfy both the material and processing requirements. However, the thermal stability of such elastomers is limited at temperatures below 200° C. and significant outgassing is observed above 100° C. We have found that the thermal stability can be significantly enhanced by the incorporation of 25 wt % or more diphenylsiloxane. Further, enhancement in the thermal stability has been demonstrated by increasing the molecular weight of the resins (oligomers) or minimizing the cross-link junction. The outgassing of the elastomers can be minimized at temperatures below 300° C. by first using a thermally transient catalyst in the resin synthesis and secondly subjecting the resin to a thin film distillation to remove low molecular weight side-products. For our experiments, we have found that 25 wt % diphenylsiloxane is optimal, balancing the desired thermal stability with the increased viscosity associated with diphenylsiloxane incorporation. The optimum number average molecular weight of the resin for maximum thermal stability was found to be between 18,000 and 35,000 g/mol. Higher molecular weights were difficult to cure and too viscous, once filled, to process. Network formation was achieved by a standard hydrosilylation polymerization using a hindered platinum catalyst in a reactive silicon oil carrier.

In FIG. 10 when bond head 124 bonds the wire 126 to the surface 122 of pad 106 there is formed a flattened spherical end shown as 104 in FIG. 6.

The high density test probe provides a means for testing high density and high performance integrated circuits in wafer form or as discrete chips. The probe contacts can be designed for high performance functional testing or high temperature burn-in applications. The probe contacts can also be reworked several times by resurfacing the rigid polymer material that encases the wires exposing the ends of the contacts.

The high density probe contacts described in this disclosure are designed to be used for testing semiconductor devices in either wafer form or as discrete chips. The high density probe uses metal wires that are bonded to a rigid substrate. The wires are imbedded in a rigid polymer that has a cup shaped recess around each to the wire ends. The cup shaped recess 112 shown in FIG. 5 provides a positive self-aligning function for chips with solder ball contacts. A plurality of probe heads 40 can be mounted onto a space transformation substrate 60 so that a plurality of chips can be probed an burned-in simultaneously.

An alternate embodiment of this invention would include straight wires instead of angled wires. Another alternate embodiment could use a suspended alignment mask for aligning the chip to the wire contacts instead of the cup shaped recesses in the top surface of the rigid polymer. The suspended alignment mask is made by ablating holes in a thin sheet of polyimide using an excimer laser and a metal mask with the correct hole pattern. Another alternate embodiment of this design would include a interposer probe assembly that could be made separately from the test substrate as described in U.S. patent application, Ser. No. 07/963,364, incorporated by reference herein above. This design could be fabricated by using a copper substrate that would be etched away after the probe assembly is completed and the polymer is cured. This approach could be further modified by using an adhesion de-promoter on the wirse to allow them to slide freely (along the axis of the wires) in the polymer material.

FIG. 14 shows an alternate embodiment of probe tip 40 of FIGS. 2 and 3. As described herein above, probe tip 40 is fabricated to be originally fixed to the surface of a first level space transformer 54. Each wire 120 is wire bonded directly to a pad 106 on substrate 60 so that the probe assembly 40 is rigidly fixed to the substrate 60. The embodiment of FIG. 14, the probe head assembly 40 can be fabricated via a discrete stand alone element. This can be fabricated following the process of U.S. patent application Ser. No. 07/963,348, filed Oct. 19, 1992, which has been incorporated herein by reference above. Following this fabrication process as described herein above, wires 42 of FIG. 14 are wire bonded to a surface. Rather than being wire bonded directly to a pad on a space transformation substrate, wire 42 is wire bonded to a sacrificial substrate as described in the application incorporated herein. The sacrificial substrate is removed to leave the structure of FIG. 14. At ends 102 of wires 44 there is a flattened ball 104 caused by the wire bond operation. In a preferred embodiment the sacrificial substrate to which the wires are bonded have an array of pits which result in a protrusion 150 which can have any predetermined shape such as a hemisphere or a pyramid. Protrusion 150 provides a raised contact for providing good electrical connection to a contact location against which is pressed. The clamp assembly 80 of FIGS. 2 and 3 can be modified so that probe tip assembly 40 can be pressed towards surface 58 of substrate 60 so that ends 104 of FIG. 14 can be pressed against contact locations such as 106 of FIG. 5 on substrate 60. Protuberances 104 are aligned to pads 100 on surface 58 of FIG. 5 in a manner similar to how the conductor ends 86 and 88 of the connector in FIG. 4 are aligned to pads 75 and 64 respectively.

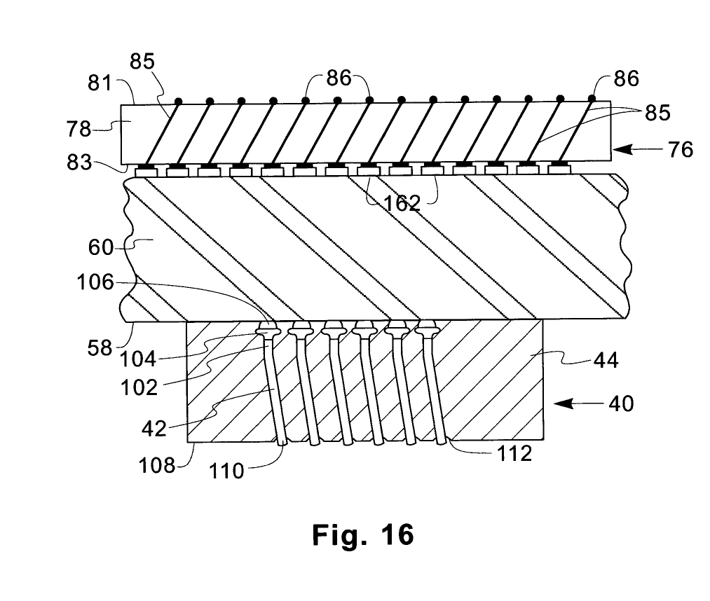

As shown in the process of FIGS. 7 to 9, wire 126 is ball bonded to pad 106 on substrate 60. An alternative process is to start with a substrate 160 as shown in FIG. 15 having contact locations 162 having an electrically conductive material 164 disposed on surface 166 of contact location 162. Electrically conductive material 164 can be solder. A bond lead such as 124 of FIG. 7 can be used to dispose end 168 of wire 170 against solder mound 164 which can be heated to melting. End 168 of wire 170 is pressed into the molten solder mound to form wire 172 embedded into a solidified solder mound 174. Using this process a structure similar to that of FIG. 5 can be fabricated.

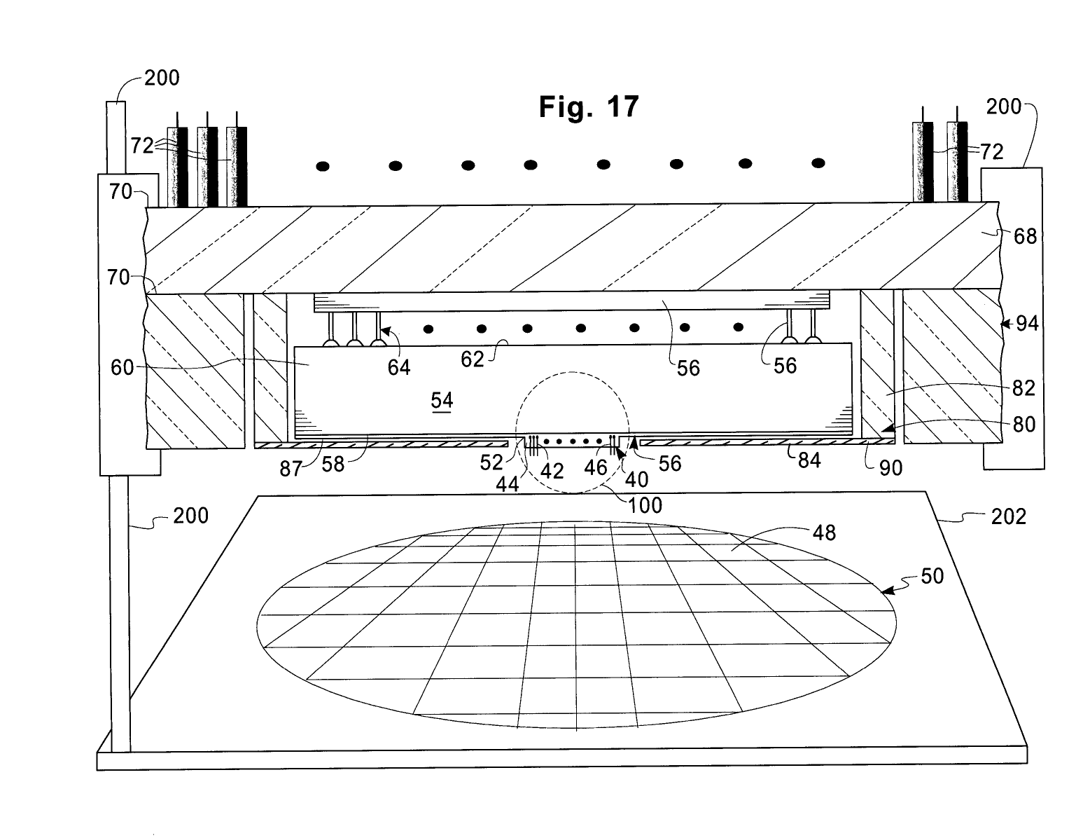

FIG. 16 shows another alternative embodiment of a method to fabricate the structure of FIG. 5.

Numerals common between FIGS. 15 and 16 represent the same thing. End 180 elongated electrical conductor 182 is held against top surface 163 of pad 162 on substrate 160. A beam of light 184 from laser 186 is directed at end 180 of elongated conductor 182 at the location of contact with surface 163 of pad 162. The end 180 is laser welded to surface 163 to form protuberance 186.

In summary, the present invention is directed to high density test probe for testing high density and high performance integrated circuits in wafer form or as discrete chips. The probe contacts are designed for high performance functional testing and for high temperature burn in applications. The probe is formed from an elastomeric probe tip having a highly dense array of elongated electrical conductors embedded in an elastomeric material which is in electrical contact with a space transformer.

While the present invention has been described with respect to preferred embodiments, numerous modifications, changes and improvements will occur to those skilled in the art without departing from the spirit and scope of the invention.

1-62. (canceled)

63. An assembly including an electronic component, the electronic component comprising:
a plurality of contact locations adjacent a surface of the electronic component,
a plurality of electrical conductors, each electrical conductors comprising,
a first end on the component that is at a position adjacent the surface of the electronic component but fanned out from a corresponding contact location,
a compliant elongated electrical conductor positioned at the first end of the electrical conductor,
an electrical connection between the corresponding terminal and the first end,
where the compliant elongated electrical conductor is free standing, having a first end fixed adjacent to the electronic component and having a second end at a position not adjacent the electronic component,
where the compliant elongated electrical conductor can be displaced such that the second end thereof moves in relation to the first end of the compliant contact structure, and
the assembly including an active semiconductor device connected to function at least in part by communication of electrical energy through at least one of the contact elements.

64. The assembly of claim 63, wherein the electronic component comprises a silicon substrate.

65. The assembly of claim 63, wherein the electronic component is mated directly with an active semiconductor device.

66. The assembly of claim 65, wherein the electronic component is a socket mated directly with and to securely connect to an active semiconductor device.

67-91. (canceled)

92. An assembly comprising:
an electronic component;
said electronic component comprising a substrate;
said substrate has a surface;
a plurality of contact locations at said surface;
a fanout member;
said fanout member comprises an electrical conductor comprising a contact location end and a fanout location end;
said contact location end is electrically connected to at least one of said plurality of contact locations at said surface;
said fanout location end is displace relative to said at least one of said plurality of contact locations;
an elongated electrical conductor comprising a first end and a second end;
said first end of said elongated electrical conductor is electrically connected to said fanout location end;
said second end of said elongated electrical conductor is not adjacent said electronic component;
said elongated electrical conductor is free standing;
said elongated electrical conductor is compliant and can be displaced so that said second end thereof moves in relation to the first end of said elongated electrical conductor; and
said assembly including an active semiconductor device connected to function by communication of electrical power through at least one said elongated electrical conductors.

93. The assembly according to claim 92, wherein said elongated electrical conductor has a coating.

94. The assembly according to claim 93, wherein said coating is selected from the groups consisting of Au, Cr, Co, Ni and Pd.

95. The assembly according to claim 92, wherein said elongated electrical conductor comprises a material selected from the group consisting of gold, aluminum, copper, nickel, palladium, gold alloy and copper alloy.

96. The assembly according to claim 92, wherein said fanout member comprises a thin film wiring structure.

97. The assembly according to claim 92, wherein said fanout member is a space transformer substrate.

98. An assembly comprising:
an electronic component;
said electronic component comprising a substrate;
said substrate has a surface;
a plurality of contact locations at said surface;
a fanout member;
said fanout member comprises an electrical conductor comprising a contact location end and a fanout location end;
said contact location end is electrically connected to at least one of said plurality of contact locations at said surface;
said fanout location end is displace relative to said at least one of said plurality of contact locations;
an elongated electrical conductor comprising a first end and a second end;
said first end of said elongated electrical conductor is electrically connected to said fanout location end;
said second end of said elongated electrical conductor is not adjacent said electronic component;
said elongated electrical conductor is free standing; and
said elongated electrical conductor is compliant and can be displaced so that said second end thereof moves in relation to the first end of said elongated electrical conductor.

99-105. (canceled)

106. A semiconductor assembly comprising:
an assembly substrate;
at least one semiconductor die; and
a plurality of free standing elongate flexible interconnection elements located between the die and the assembly substrate, each having a first portion contacting the assembly substrate and a second portion contacting the semiconductor die, each elongate flexible interconnection element extends from one of the semiconductor die and the assembly substrate, whereafter the elongate flexible interconnection element alters direction at least once, and each elongate flexible interconnection element includes an elongate flexible element of a first material, and a second material on the elongate flexible element wherein the elongate flexible element with the second material thereon is compliant.

107. The semiconductor assembly of claim 106, wherein the substrate has a first set of contact pads and the semiconductor die has a second set of contact pads and each elongate flexible interconnection element has a first portion contacting a respective contact pad of the first set of contact pads, and a second portion contacting a respective contact pad of the second set of contact pads.

108. The semiconductor assembly of claim 106, wherein the elongate flexible interconnection element has a portion permanently attached to the assembly substrate.

109. An electronic assembly comprising:
a first substrate having a first set of contact pads;
a second substrate having a second set of contact pads; and
a plurality of elongate flexible interconnection elements located between the first substrate and the second substrate, each being free standing and having a portion permanently attached to a respective contact pad of the first set of contact pads and a second portion contacting a respective contact pad of the second set of contact pads, each elongate flexible interconnection element extending from the first substrate, whereafter the elongated flexible interconnection element alters direction at least once, each elongated flexible interconnection element including an elongated flexible element of a first material, and a second material on the elongated flexible element wherein the elongate flexible element with the second material thereon is compliant, the first and second substrates being brought into fixed relationship relative to one another.

110. The electronic assembly of claim 109, wherein one of the substrates comprises a material selected from the group consisting of a semiconductor die, a printed circuit board, a plastic substrate, a ceramic substrate, and a polymer based substrate.

111. The electronic assembly of claim 109, wherein one of the substrates is a semiconductor die.

112. The electronic assembly of claim 109, wherein the second substrate is a semiconductor die.

113. The electronic assembly of claim 109, wherein, for each interconnection element of a first plurality of the free standing interconnection elements, a contact region distant from the substrate on a given interconnection element is substantially in a common plane with corresponding contact regions of the first plurality of interconnection elements.

114. The electronic assembly of claim 109, wherein the elongated flexible element has a portion connected to a respective terminal of the first set of contact pads.

115. The electronic assembly of claim 114, wherein an end of the elongate flexible element is connected to the respective terminal.

116. The electronic assembly of claim 109, wherein the second material passivates of the interconnection element.

117. The electronic assembly of claim 109, wherein the first material includes a material selected from the group consisting of gold, aluminum, copper, nickel, palladium, gold alloy and copper alloy.

118. The electronic assembly of claim 109, wherein the first material includes a material selected from the group consisting of gold, aluminum and copper.

119. The electronic assembly of claim 109, wherein the elongate flexible element has a cross-dimension of between 0.001 and 0.005 inches.

120. The electronic assembly of claim 109, wherein the elongate flexible element is a wire.

121. The electronic assembly of claim 109, wherein the second material is connected to the respective terminal.

122. The electronic assembly of claim 109, wherein the second material is stronger than the elongate flexible element.

123. The electronic assembly of claim 109, wherein the second material is a coating which is deposited around the elongate flexible element.

124. The electronic assembly of claim 109, wherein the second material comprises a material selected from the group consisting of nickel, cobalt, copper, gold, platinum and palladium.

125. The electronic assembly of claim 109, wherein the second material comprises a material selected from the group consisting of nickel and cobalt.

126. The electronic assembly of claim 109, wherein the second material is a thin layer.

127. The electronic assembly of claim 109, wherein the second material is selected from the group consisting of an electroplated, electrolessly plated, sputtered and e-beam evaporated coating.

128. The electronic assembly of claim 109, wherein the elongate flexible element has a cross-dimension of between 0.001 and 0.005 inches and the second material is a thin layer.

129. The electronic assembly of claim 109, wherein the first material and the second material are both conductive.

130. The electronic assembly of claim 129, wherein the second material is formed directly on the elongate element.

131. The electronic assembly of claim 109, wherein the first material comprises a material selected from the group consisting of gold, gold alloy, copper, copper alloy, aluminum, nickel and the second material is selected from the group consisting of Au, Cr, Co, Ni and Pd.

132. The electronic assembly of claim 109, wherein the first material includes a material selected from the group consisting of gold, aluminum and copper, and the second material includes a material selected from the group consisting of nickel and cobalt.

133. The electronic assembly of claim 109, wherein the elongate flexible element is a core element and the second material is located around the core element.

134. A structure comprising:
an assembly substrate;
at least one semiconductor die; and
a plurality of free standing elongate flexible interconnection elements located between the die and the assembly substrate, each having a first portion contacting the assembly substrate and a second portion contacting the semiconductor die, each elongate flexible interconnection element extends from one of the semiconductor die and the assembly substrate, whereafter the elongate flexible interconnection element alters direction at least once, and each elongate flexible interconnection element includes an elongate flexible element of a first material, and a second material on the elongate flexible element wherein the elongate flexible element with the second material thereon is compliant.

135. A structure comprising:
a first substrate having a first set of contact pads;
a second substrate having a second set of contact pads; and
a plurality of elongate flexible interconnection elements located between the first substrate and the second substrate, each being free standing and having a portion permanently attached to a respective contact pad of the first set of contact pads and a second portion contacting a respective contact pad of the second set of contact pads, each elongate flexible interconnection element extending from the first substrate, whereafter the elongate flexible interconnection element alters direction at least once, each elongate flexible interconnection element including an elongate flexible element of a first material, and a second material on the elongate flexible element wherein the elongate flexible element with the second material thereon is compliant, the first and second substrates being brought into fixed relationship relative to one another.

136. The semiconductor assembly of claim 106, wherein said assembly is a probe for a semiconductor device.

137. The semiconductor assembly of claim 106, wherein said assembly is a connector for a semiconductor device.

138. The semiconductor assembly of claim 109, wherein said assembly is a probe for a semiconductor device.

139. The semiconductor assembly of claim 109, wherein said assembly is a connector for a semiconductor device.

140. The semiconductor assembly of claim 106, wherein said structure is a probe for a semiconductor device.

141. The semiconductor assembly of claim 106, wherein said structure is a connector for a semiconductor device.

142. The semiconductor assembly of claim 109, wherein said structure is a probe for a semiconductor device.

143. The semiconductor assembly of claim 109, wherein said structure is a connector for a semiconductor device.

144. A semiconductor device comprising:
a silicon body having a plurality of contact locations;
a plurality of free-standing elongated electrical conductors, each of the elongated electrical conductors having a first end, a second end, and a compliant section between the first end and the second end, selected ones of the free-standing elongated electrical conductors each mounted by a first end thereof to and extending from a respective selected one of the contact locations and the respective compliant section thereof flexing against compliant action when a force is applied to the respective second end thereof and to compliantly respond when the force is relieved; and
the second ends of the elongated electrical conductors are at an angle with respect to said first end and the contact location, the angle being between a minimum and a maximum value.

145. A semiconductor device, according to claim 144, wherein:
the elongated electrical conductors having a second end at an angle with respect to the first end have a bend to accommodate the angle between the minimum and maximum angle.

146. A semiconductor device, according to claim 145, wherein:
the contact locations are disposed a first distance apart;
the second ends of the elongated electrical conductors are disposed at a second distance apart; and
the second distance is determined by the angle.

147. A semiconductor device, according to claim 146, wherein:
the first distance is approximately 5 mils.

148. A semiconductor device, according to claim 145, further comprising:
a dielectric material extending over a surface of the silicon body and enveloping a portion of the elongated electrical conductors.

149. A semiconductor device, according to claim 145, wherein:
the silicon body is covered by an electrically insulating coating having holes and comprises electrically conductive throughholes and electrical conductors electrically connected to the contact locations.

150. A semiconductor device, according to claim 145, further comprising:
metallization covering the elongated electrical conductors.

151. A semiconductor device, according to claim 145, wherein:
the elongated electrical conductors are composite structures.

152. A semiconductor device, according to claim 145, wherein:
the contact structures are resilient contact structures.

153. An electronic assembly comprising:
a substrate having a plurality of contact locations on the one side thereof; and
a plurality of resilient, elongated electrical conductors, wherein:
(i) each elongated electrical conductor has a first end attached to a respective one of the contact locations, and a second end, distant from the substrate, the second ends of the elongated electrical conductors are at an angle with respect to the first end of the elongated electrical conductor and the contact location, the angle being between a minimum and maximum value and the first end of a first of the elongated electrical conductors is spaced from the first end of a second, adjacent one of the elongated electrical conductors by a first distance and the second end of the first elongated electrical conductor is spaced from the second end of the second elongated electrical conductor by a second distance which is determined by the angles corresponding to the first and second elongated electrical conductors; and
(ii) each elongated conductor comprises a flexible elongated element, and a second material on the flexible elongated element, the flexible elongated element having a first composition and the second material having a second composition which is different from the first composition.

154. The electronic assembly of claim 153, wherein the first composition comprises a material selected from the group consisting of gold, aluminum, copper, nickel, platinum, gold alloy, copper alloy and palladium.

155. The electronic assembly of claim 153, wherein the first material comprises gold.

156. The electronic assembly of claim 153, wherein the second material is selected from the group consisting of Au, Cr, Co, Ni and Pd.

157. The electronic assembly of claim 153, wherein at least one layer of the second material is selected from the group consisting of nickel and cobalt.

158. The electronic assembly of claim 153, wherein the flexible elongated electrical conductor has disposed thereon the second material.

159. The electronic assembly of claim 153, wherein the second material is selected from the group consisting of an electroless plated coating, an e-beam deposited coating, a sputter deposited coating and an electroplated coating.

160. An electronic assembly comprising:
a substrate having a plurality of contact locations on one side thereof; and
a plurality of flexible elongated electrical conductors, each flexible elongated electrical conductor having a first end attached to a respective one of the contact locations and a second end, distant from the substrate, which are resiliently depressible towards the substrate, the second ends of the elongated electrical conductors are at an angle with respect to the first end of the elongated electrical conductor and the contact location, the angle being between a minimum and maximum value wherein:
(i) the first ends of two of the flexible elongated electrical conductors located next to one another are spaced by a first distance from one another; and
(ii) the second ends of the two elongated electrical conductors are spaced by a second distance from one another which is determined by the angle corresponding to the first and second elongated electrical conductors both
(a) when the two flexible elongated electrical conductors are not depressed towards the substrate and
(b) when the second ends are depressed towards the substrate; and
(iii) each elongated electrical conductor comprises a flexible elongated element of a first material, and a second material on the flexible elongated element, the flexible elongated element having a first composition and the second material having a second composition which is different from the first composition.

161. The electronic assembly of claim 160, wherein the second end of each flexible elongated electrical conductor is an area of the flexible elongated electrical conductor which is most distant from the substrate and remains most distant both when the flexible elongated electrical conductor is not depressed towards the substrate and when the second end is depressed towards the substrate.

162. An electronic assembly comprising:
a substrate having a plurality of contact locations on one side thereof; and
a plurality of flexible elongated electrical conductors, each flexible elongated electrical conductor having a first end attached to a respective one of the contact locations, and a second end most distant from the substrate, the second ends of the elongated electrical conductors are at an angle with respect to the first end of the elongated electrical conductor and the contact location, the angle being between a minimum and maximum value, the flexible elongated electrical conductor is resiliently depressible towards the substrate, wherein the first locations of two of the flexible elongated electrical conductor located next to one another are spaced from one another by a first distance and the second ends of the two elongated electrical conductors are spaced from one another by a second distance which is determined by the angles corresponding to the first and second flexible elongated electrical conductors, the second ends of each of the two flexible elongated electrical conductors being an area of the flexible elongated electrical conductor which is most distant from the substrate and remaining most distant from the substrate after depression of the second end towards the substrate, each flexible elongated electrical conductor comprising a flexible elongated element of a first material, and a second material on the flexible elongated element, the flexible elongated electrical conductor having a first composition and the second material having a second composition.

163. A semiconductor device comprising:
a silicon body having a plurality of contact locations; and
a plurality of free-standing elongated electrical conductors, each of the free-standing elongated electrical conductors having a first end, a second end, a first portion having a first bend, and a second portion having a second bend selected ones of the free-standing elongated electrical conductors mounted by a respective first end thereof to and extending from a respective selected one of the contact locations, the second ends of the elongated electrical conductors are at an angle with respect to the first end of the elongated electrical conductor and the contact location, the angle being between a minimum and maximum value; wherein the second ends of at least a portion of the elongated electrical conductors are spaced apart as determined by the angles corresponding to the first and second elongated electrical conductors.

164. A semiconductor device comprising:
a silicon body having a plurality of contact locations; and
a plurality of free-standing elongated electrical conductors, and each of the free-standing elongated electrical conductors having a first end and a second end, selected ones of the free-standing elongated electrical conductors mounted by a respective first end thereof to and extending from a respective selected one of the contact locations, the second ends of the elongated electrical conductors are at an angle with respect to the first end of the elongated electrical conductor and the contact location, the angle being between a minimum and maximum value; wherein
(i) the contact locations are spaced approximately 5 mils apart; and
(ii) the second ends are spaced as determined by the angles corresponding to the first and second elongated electrical conductors.

165. A semiconductor device comprising:
a silicon body having a plurality of contact locations;
a plurality of free-standing elongated electrical conductors, each of the free-standing elongated electrical conductors having a first end and a second end, selected ones of the free-standing elongated electrical conductors mounted by a respective first end thereof to and extending from a respective selected one of the contact locations, the second ends of the elongated electrical conductors are at an angle with respect to the first end of the elongated electrical conductor and the contact location, the angle being between a minimum and maximum value, wherein second ends of at least a portion of the elongated electrical conductors are spaced apart as determined by the angles corresponding to the first and second elongated electrical conductors; and
a dielectric material extending over a surface of the silicon body and enveloping a portion of the elongated electrical conductors.

166. A semiconductor device comprising:
a silicon body having a plurality of contact locations;
a plurality of free-standing elongated electrical conductors, each of the free-standing elongated electrical conductors having a first end and a second end, selected ones of the free-standing elongated electrical conductors mounted by a respective first end thereof to and extending from a respective selected one of the contact locations, wherein the second ends of the elongated electrical conductors are at an angle with respect to the first end of the elongated electrical conductor and the contact location, the angle being between a minimum and maximum value:
(i) second ends of at least a portion of the second ends are spaced as determined by the angles corresponding to the first and second elongated electrical conductors;
(ii) the silicon body is covered by an electrically insulating coating having through holes therethrough whereby the contact locations are accessible through the electrically insulating coating;
(iii) a plurality of additional conductive material elements extend through the passivation layer to contact the contact locations; and
(iv) the elongated electrical conductor are mounted to the additional conductive material.

167. A semiconductor device, according to claim 166, further comprising:
metallization covering the elongated electrical conductor.

168. An electronic assembly comprising:
a substrate having a plurality of contact locations on one side thereof; and
a plurality of resilient, elongated electrical conductors:
(i) each elongated electrical conductor has a first end attached to a respective one of the contact locations, and a second end, distant from the substrate, the second end of the elongated electrical conductor is at an angle with respect to the first end of the elongated electrical conductor and the contact location, the angle being between a minimum and maximum value, and the first end of a first of the elongated electrical conductors is spaced from the first end of a second, adjacent one of the elongated electrical conductors by a first distance and the second end of the first elongated electrical conductor is spaced from the second end of the second elongated electrical conductor by a second distance which is determined by the angles corresponding to the first and second elongated electrical conductors;
(ii) each elongated electrical conductor comprises a flexible elongated element of a first material being gold, and a second material on the flexible elongated element, the flexible elongated element having a first composition and the coating having a second composition which is different from the first composition.

169. An electronic assembly comprising:
a substrate having a plurality of contact locations on one side thereof; and
a plurality of resilient, elongated electrical conductors:
(i) each elongated electrical conductor has a first end attached to a respective one of the contact locations, and a second end, distant from the substrate, wherein the second end of the elongated electrical conductor is at an angle with respect to the first end of the elongated electrical conductor and the contact location, the angle being between a minimum and maximum value, and the first end of a first of the elongated electrical conductors is spaced from the first end of a second, adjacent one of the elongated electrical conductors by a first distance and the second end of the first elongated electrical conductor is spaced from the second end of the second elongated electrical conductor by a second distance which is determined by the angles corresponding to the first and second elongated electrical conductors; and
(ii) each elongated electrical conductor comprises a flexible elongated electrical conductor of a first material, and a second material on the flexible elongated element, the flexible elongated element having a first composition and the coating having a second composition which is different from the first composition.

170. An electronic assembly comprising:
a substrate having a plurality of contact locations on one side thereof; and
a plurality of resilient, elongated electrical conductors:
(i) each elongated electrical conductor has a first end attached to a respective one of the contact locations, and a second end, distant from the substrate wherein the second ends of the elongated electrical conductors are at an angle with respect to the first end of the elongated electrical conductor and the contact location, the angle being between a minimum and maximum value, and the first contact location of a first of the elongated electrical conductors is spaced from the first end of a second, adjacent one of the elongated electrical conductors by a first distance and the second end of the first elongated electrical conductor is spaced from the second end of the second elongated electrical conductor by a distance which is determined by the angles corresponding to the first and second elongated electrical conductors; and
(ii) each elongated electrical conductor comprises a flexible elongated element of a first material, and a second material, comprising nickel iron or cobalt, on the flexible elongated element, the flexible elongated element having a first composition and the coating having a second composition which is different from the first composition.

171. An electronic assembly comprising:
a substrate having a plurality of contact locations on one side thereof; and
a plurality of resilient, elongated electrical conductors:
(i) each elongated electrical conductor has a first end attached to a respective one of the contact locations, and a second end, distant from the substrate wherein the second ends of the elongated electrical conductors are at an angle with respect to the first end of the elongated electrical conductor and the contact location, the angle being between a minimum and maximum value, and the first end of a first of the elongated electrical conductor is spaced from the first end of a second, adjacent one of the elongated electrical conductors by a first distance and the second ends of the first elongated electrical conductor is spaced from the second end of the second elongated electrical conductor by a second distance which is determined by the angles corresponding to the first and second elongated electrical conductors; and
(ii) each elongated electrical conductor comprises a flexible elongated element of a first material, and a second material on the flexible elongated element, the flexible elongated element having a first composition and the coating having a second composition which is different from the first composition.

172. A semiconductor device according to any one of claims 144, 163, 164, 165 or 166, wherein the minimum value is 5 degrees and the maximum value is 60 degrees.

173. A semiconductor device according to any one of claims 144, 163, 164, 165 or 166, wherein as a result of the angle being between the minimum and the maximum values, the second ends are at a spacing different than the spacing of the first ends.

174. An electronic assembly according to anyone of claims 153, 160, 162, 168, 169, 170 or 171, wherein the minimum value is 5 degrees and the maximum value is 60 degrees.

175. An electronic assembly according to anyone of claims 153, 160, 162, 168, 169, 170 or 171, wherein as a result of the angle being between the minimum and the maximum values, the second ends are at a spacing different than the spacing of the first ends.

176. A structure comprising:
a substrate having a plurality of contact locations thereon;
a plurality of elongated electrical conductors, each having a first end and a second end;
said first end is electrically connected to one of said contact locations;
the second end of the elongated electrical conductor is at an angle with respect to said first end and said contact location to which said first end is electrically connected, the angle being between a minimum and a maximum value.

177. A structure according to claim 176, wherein the minimum value is 5 degrees and the maximum value is 60 degrees.

178. A structure according to claim 176, wherein as a result of the angle being between said minimum and said maximum values, the second ends are at a spacing different than the spacing of the first ends.

179. A structure according to claim 176, further including a coating on said elongated electrical conductors.

180. A structure according to claim 179, wherein the elongated electrical conductor comprises a first material and the coating comprises a second material.

181. A structure according to claim 180, wherein the second material is different then said first material.

182. A structure according to claim 176, wherein the elongated electrical conductor comprises a material selected from the group consisting of gold, aluminum, nickel, platinum, gold alloy, copper alloy and palladium.

183. A structure according to claim 179, wherein said coating comprises a material selected from the group consisting of Au, Cr, Co, Ni and Pd.

184. A structure according to claim 176, wherein said substrate comprises silicon.

185. A structure according to claim 176, wherein said substrate comprises an electrically insulating coating.

186. A structure according to claim 176, wherein said substrate comprises electrical conductors and electrically conductive throughholes electrically interconnected to the contact locations and to the electrical conductors.

187. A structure according to claim 176, wherein said elongated electrical conductor is compliant and can be displaced so that the second end thereof moves in relation to the first end of said elongated conductor when the second end is pressed against a surface.

188. A structure according to claim 176, wherein said elongated electrical conductor compliantly responds when said second end is released from being pressed against said surface.

189. A semiconductor structure according to anyone of claims 144, 163, 164, 165 or 166, wherein the angle is nonorthogonal to the contact location.

190. An electronic assembly according to anyone of claims 153, 160, 162, 168, 169, 170, or 171, wherein the angle is nonorthogonal to the contact location.

191. A structure according to anyone of claims 176 to 190 or 192 to 194, wherein said angle is nonorthogonal to said one of said contact locations.

192. A structure according to anyone of claims 176 to 191 or 193 to 194, wherein the elongated electrical conductors are free-standing.

193. A structure according to anyone of claims 176 to 192 or 194, further including a dielectric material disposed on said substrate and enveloping a portion of said elongated electrical conductor.

194. A structure according to anyone of claims 176 to 193, wherein said elongated electrical conductors are compliant.

195. A structure comprising:
a substrate having first and second opposed sides with a first set of contact locations on the first side and a second set of contact locations on the second side;
a first set of resilient elongated electrical conductors, each having a first end electrically interconnected to a respective one of the contact locations of the first set of contact locations,
a second end distant from the substrate, and an elongated section extending from the first end to the second end, the elongated section resiliently bending upon depression of the second end towards the substrate, the second ends of the elongated electrical conductors are at an angle with respect to the first end of the elongated electrical conductor and the contact location, the angle being between a minimum and a maximum value, wherein the second ends of two adjacent resilient contact structures are spaced as determined by the angles corresponding to the first and second elongated electrical conductors and wherein respective ones of the second set of contact locations are coupled to corresponding ones of the first set of contact locations; and
a second set of resilient elongated electrical conductors, each having a first end electrically interconnected to a respective one of the contact locations of the second set of contact locations, a second end distant from the substrate, and an elongate section extending from the first end to the second end, the elongated section resiliently bending upon depression of the second end towards the substrate.

196. A structure, according to claim 195, further comprising:
an enlargement at ends of the first plurality of resilient elongated electrical conductors.

197. A structure, according to claim 195, wherein:
the first plurality of resilient contact structures are composite electrical interconnection elements.

198. A structure, according to claim 195, wherein:
the first plurality of resilient elongated electrical conductors are fabricated on a sacrificial substrate prior to electrical interconnections of the first plurality of elongated electrical conductors to the first plurality of contact locations.

199. A structure, according to claim 195, further comprising:
a subset of the second set of elongated electrical conductors directly electrically interconnected to the second set of contact locations.

200. A structure, according to claim 199, wherein:
the second plurality of elongated electrical conductors are composite interconnection elements.

201. A structure, according to claim 199, wherein:
the second plurality of resilient elongated electrical conductors are fabricated on a sacrificial substrate prior to electrically interconnecting the second plurality of resilient elongated electrical conductors to the second plurality of contact locations.

202. A Probe Assembly, comprising:
a second space transformer having a first surface, a second surface and a first plurality of contact locations on the first surface thereof;
an interconnection structure having a first surface, a second surface, a second plurality of elongated resilient electrical conductors extending from the second surface thereof and a first plurality of elongated resilient electrical conductors extending from the first surface thereof; and
a first space transformer having a first surface, a second surface, a plurality of contact locations disposed on the second surface thereof, and a third plurality of elongated resilient conductors extending from the first surface thereof; wherein:
the second plurality of elongated resilient electrical conductors effect a pressure connection with the contact locations of the second space transformer; and
the first plurality of elongated resilient electrical conductors effect a pressure connection with the contact locations of the first space transformer.

203. A Probe Assembly, according to claim 202, wherein:
the third plurality of elongated resilient electrical conductors are electrically interconnected to contact locations on the first surface of the first space transformer.

204. A Probe Assembly, according to claim 202, wherein:
the first plurality of elongated resilient electrical conductors are composite electrical interconnection elements.

205. A Probe Assembly, according to claim 202, wherein:
the second plurality of elongated resilient electrical conductors are composite electrical interconnection elements.

206. A Probe Assembly, according to claim 202, wherein:
the third plurality of elongated resilient electrical conductors are composite electrical interconnection elements.

207. A Probe Assembly, according to claim 202, wherein:
one or more of the first plurality of elongated resilient electrical conductors are a composite structure comprising an elongated element and a coating.

208. A Probe Assembly, according to claim 202, wherein:
one or more of the second plurality of elongated resilient electrical conductors are a composite structure comprising an elongated element and a coating.

209. A structure, according to claim 202, further comprising:
a clamp for holding the first space transformer in place with respect to said second space transformer,
the clamp comprises a sheet of material supported by a member perpendicularly disposed with respect to the second space transformer;
means for affixing the sheet to the member; and
means for urging the first space transformer towards the first surface of the second space transformer.

210. A Probe Assembly, according to claim 209, wherein said clamps comprises a sheet made of aluminum.

211. A Probe Assembly, according to claim 209, wherein the means for urging the first space transformer comprises:
the sheet of material; and
a screw holding the sheet in place with respect to the member and the second space transformer with the first space transformer captured therebetween.

212. A Probe Assembly, according to claim 211, wherein:
said sheet comprises aluminum.

213. A Probe Assembly, according to claim 211, further comprising:
a member perpendicularly disposed with respect to the second space transformer for supporting the sheet of material.

214. A Probe Assembly, according to claim 209, wherein the clamp comprises means for affixing a sheet of material supported by a member perpendicularly despired with respect to the second space transformer, the sheet is held in place to the member by a screw forming the clamp to hold the first space transformer in place with respect to the second space transformer.

215. A Probe Assembly, according to claim 214, wherein:
the sheet and the member are made of aluminum.

216. A Probe Assembly, according to claim 202, further comprising:
means for aligning of the first space transformer relative to the second space transformer.

217. A Probe Assembly, according to claim 216, wherein the means for aligning the first space transformer comprises:
a plurality of pins disposed on the first space transformer.

218. A Probe Assembly, according to claim 216, wherein the means for aligning the first space transformer comprises:
a plurality of projections for mating with grooves on the interconnection structure.

219. A Probe Assembly, according to claim 202, wherein:
the contact locations are disposed at a first pitch on the second surface of the second space transformer;
the third plurality of elongated resilient electrical conductors are disposed at a second pitch on the first surface of the second space transformer.

220. A Probe Assembly, according to claim 202, wherein:
the first plurality of elongated resilient electrical conductors are disposed at a first pitch on the first surface of the interconnection structure;
the second plurality of elongated resilient electrical conductors are disposed at a second pitch on the second surface of the interconnection structure.

221. A Probe Assembly, according to claim 202, wherein:
the contact locations are disposed at a first pitch on the second surface of the first space transformer;
the third plurality of elongated resilient electrical conductors are disposed at a second pitch on the first surface of the second space transformer;
the first plurality of elongated resilient electrical conductors are disposed at the first pitch on the first surface of the interconnection structure;
the second plurality of elongated resilient electrical conductors are disposed at the first pitch on the second surface of the interconnection structure.

222. A Probe Assembly, according to claim 202, wherein at least some of the elongated resilient electrical conductors comprise:
a composite interconnection element having an end; and
a tip structure disposed at the end of the composite interconnection element.

223. A structure, according to claim 202, wherein:
the third plurality of elongated resilient electrical conductors are electrically interconnected to contact locations on the first surface of the first space transformer.

224. A structure, comprising:
a first space transformer having a first surface, a second surface, a plurality of contact locations disposed on the second surface thereof, and a plurality of elongated electrical conductors connected to the first surface thereof, said first space transformer adapted in use such that ends of the plurality of elongated electrical conductors for making pressure contacts with a corresponding plurality of contact locations on a semiconductor wafer; and
an interconnection structure having a first surface, a second surface, a first plurality of elongated resilient electrical conductors extending from the first surface thereof, said electrical interconnection structure adapted in use such that contact regions of the first plurality of elongated resilient electrical conductors make pressure connections with the plurality of contact locations on the second surface of the first space transformer, the electrical interconnection structure having a second plurality of elongated resilient electrical conductors extending from the second surface thereof, said interconnection structure adapted in use for contact locations of the second plurality of elongated resilient electrical conductors making pressure connections with a plurality of contact locations on a second space transformer.

225. A structure, according to claim 224, wherein:
the contact locations are disposed at a first pitch on the second surface of the first space transformer;
the plurality of elongated electrical conductors are disposed at a second pitch on the first surface of the first space transformer.

226. A structure, according to claim 224, wherein:
the second plurality of elongated resilient electrical conductors are disposed at a first pitch on the second surface of the interconnection structure;
the first plurality of elongated resilient electrical conductors are disposed at a second pitch on the first surface of the interconnection structure.

227. A structure, according to claim 224, wherein:
the contact locations are disposed at a first pitch on the second surface of the space transformer;
the plurality of elongated resilient electrical conductors are disposed at a second pitch on the first surface of the space transformer;
the second plurality of elongated resilient electrical conductors are disposed at the first pitch on the second surface of the electrical interconnection structure;
the first plurality of elongated resilient electrical conductors are disposed at the first pitch on the first surface of the electrical interconnection structure.

228. A Probe Assembly, comprising:
a second space transformer having a first surface, a second surface and a plurality of second contact locations on the first surface thereof;
a first space transformer having a first surface, a second surface, a plurality of first contact locations disposed on the second surface thereof, and a first plurality of elongated resilient electrical conductors mounted adjacent to and extending from the first surface thereof;
wherein the plurality of first contact locations are connected to the plurality of second contact locations of the second space transformer.

229. A Probe Assembly, according to claim 228, wherein:
the first plurality of elongated resilient electrical conductors are mounted directly to contact locations on the first surface of the first space transformer.

230. A Probe Assembly, according to claim 228, wherein:
the first plurality of elongated resilient electrical conductors are connected to contact locations on the first surface of the first space transformer.

231. A Probe Assembly, according to claim 228, wherein:
the first plurality of elongated resilient electrical conductors are composite interconnection elements.

232. A Probe Card Assembly, according to claim 228, further comprising:
means for aligning the first space transformer relative to the second space transformer.

233. A Probe Assembly, according to claim 232, wherein the means for aligning the first space transformer comprises:
a plurality of pins disposed on the first space transformer.

234. A Probe Assembly, according to claim 232, wherein the means for aligning the first space transformer comprises:
a plurality of engaging projections and grooves.

235. A Probe Assembly, according to claim 228, wherein:
the contact locations are disposed at a first pitch on the second surface of the first space transformer;
the first plurality of elongated resilient electrical conductors each having a second end, the second ends of the elongated electrical conductors are at an angle with respect to the first end of the elongated electrical conductor and the contact location, the angle being between a minimum and a maximum value, the second ends are disposed at a second pitch as determined by the angles corresponding to the first plurality of elongated resilient electrical conductors; and
the first pitch is a shortest distance between any two adjacent contact pads and the second pitch is a shortest distance between any two adjacent elongate electrical conductors.

236. A Probe Assembly, comprising:
a second space transformer having a first surface, a second surface and a plurality of second contact locations on the first surface thereof;
a first space transformer having a first surface, a second surface, a plurality of first contact locations disposed on the second surface thereof, and a first plurality of elongated electrical conductors electrically connected adjacent to and extending from the first surface thereof;
wherein the plurality of first contact locations are connected to the plurality of second contact locations of the second substrate.

237. A Probe Assembly, according to claim 236, wherein:
the first plurality of elongated electrical conductors are electrically interconnected to contact locations on the first surface of the first space transformer.

238. A Probe Assembly, according to claim 236, wherein:
the first plurality of elongated electrical conductors are electrically interconnected to contact locations on the first surface of the first space transformer.

239. A Probe Assembly, according to claim 236, wherein:
the first plurality of elongated electrical conductors are composite interconnection elements.

240. A Probe Assembly, according to claim 236, further comprising:
means for aligning the first space transformer relative to the second space transformer.

241. A Probe Assembly, according to claim 240, wherein the means for aligning the first space transformer comprises:
a plurality of pins disposed on the first space transformer.

242. A Probe Assembly, according to claim 240, wherein the means for aligning the first space transformer comprises:
a plurality of engaging projections and grooves.

243. A Probe Assembly, according to claim 236, wherein:
the contact locations are disposed at a first pitch on the second surface of the space transformer;
the first plurality of elongated electrical conductors each having a second end, the second end of the elongated electrical conductors are at an angle with respect to the first end of the elongated electrical conductor and the contact location, the angle being between a minimum and a maximum value, the second ends are disposed at a second pitch as determined by the angles corresponding to the first and second elongated electrical conductors; and
the first pitch is a shortest distance between any two adjacent contact pads and the second pitch is a shortest distance between any two adjacent elongated electrical conductors.

244. A Probe Assembly, according to claim 219, wherein the first pitch is greater than the second pitch.

245. A Probe Assembly, according to claim 220, wherein the first pitch is substantially the same as the second pitch.

246. A Probe Assembly, according to claim 221, wherein the first pitch is greater than the second pitch.

247. A structure, according to claim 225, wherein the first pitch is greater than the second pitch.

248. A structure, according to claim 226, wherein the first pitch is substantially the same as the second pitch.

249. A structure, according to claim 227, wherein the first pitch is greater than the second pitch.

250. A structure comprising:
a substrate having first and second opposed sides with a first set of contact locations on the first side and a second set of contact locations on the second side;
a first set of resilient elongated electrical conductors, each having a first end electrically interconnected to a respective one of the contact locations of the first set of contact locations,
a second end distant from the substrate, and an elongated section extending from the first end to the second end, the elongated section resiliently bending upon depression of the second end towards the substrate, the second ends of the elongated electrical conductors are at an angle with respect to the first end of the elongated electrical conductor and the contact location, the angle being between a minimum and a maximum value, wherein the second ends of two adjacent resilient contact structures are spaced as determined by the angles corresponding to the first and second elongated electrical conductors and wherein respective ones of the second set of contact locations are coupled to corresponding ones of the first set of contact locations; and
a second set of elongated electrical conductors, each having a first end electrically interconnected to a respective one of the contact locations of the second set of contact locations, a second end distant from the substrate, and an elongate section extending from the first end to the second end.

251. A structure, according to claim 250, further comprising:
an enlargement at ends of the first plurality of resilient elongated electrical conductors.

252. A structure, according to claim 250, wherein:
the first plurality of resilient contact structures are composite electrical interconnection elements comprising a first enlargement at the first end, a second enlargement at the second end and an electrically conductive wire electrically interconnecting the first enlargement and the second enlargement.

253. A structure, according to claim 250, wherein:
the first plurality of resilient elongated electrical conductors are fabricated on a sacrificial substrate prior to electrical interconnection of the first plurality of elongated electrical conductors to the first plurality of contact locations.

254. A structure, according to claim 250, further comprising:
a subset of the second set of elongated electrical conductors, directly electrically interconnected to the second set of contact locations.

255. A structure, according to claim 254, wherein:
the second plurality of elongated electrical conductors are composite interconnection elements comprising:
a first enlargement at the first end
a second enlargement at the second end; and
an electrically conductive wire electrically interconnecting the first enlargement and the second enlargement.

256. A structure, according to claim 250, wherein:
the second set of elongated electrical conductors are resilient.

257. A structure, according to claim 250, wherein:
the second set of elongated electrical conductors are pins.

258. A structure, according to claim 250, further including:
a dielectric material disposed on said first surface enveloping a part of said first set of resilient elongated electrical conductors.

259. A structure, according to claim 258, wherein:
the second set of elongated electrical conductors are resilient and further including a dielectric material disposed on the second surface and enveloping a part of the second set of elongated electrical conductors.

260. A structure, according to claim 251, wherein:
the second plurality of resilient elongated electrical conductors are fabricated on a sacrificial substrate prior to electrically interconnecting the second plurality of resilient elongated electrical conductors to the second plurality of contact locations.

261. A Probe Assembly, comprising:
a second space transformer having a first surface, a second surface and a first plurality of contact locations on the first surface thereof;
an interconnection structure having a first surface, a second surface, a second plurality of electrical conductors extending from the second surface thereof and a first plurality of electrical conductors extending from the first surface thereof; and
a first space transformer having a first surface, a second surface, a plurality of contact locations disposed on the second surface thereof, and a third plurality of elongated resilient electrical conductors extending from the first surface thereof; wherein:
the second plurality of electrical conductors effect a pressure connection with the contact locations of the second space transformer; and
the first plurality of electrical conductors effect a pressure connection with the contact locations of the first space transformer.

262. A Probe Assembly, according to claim 261, wherein:
the interconnection structure comprises a dielectric material comprising a plurality of elongated electrical conductors embedded therein;
a plurality of first ends of which comprise the first plurality of electrical conductors and a plurality of second ends of which comprise the second plurality of electrical conductors.

263. A Probe Assembly, according to claim 261, wherein:
the second plurality of electrical conductors are pins.

264. A structure, according to claim 261, further including:
a dielectric material disposed on said first surface of the interconnecting structure enveloping a part of said first set of resilient elongated electrical conductors.

265. A Probe Assembly, according to claim 264, wherein:
the first set of electrical conductors are elongated and resilient and further including a dielectric material disposed on the first surface and enveloping a part of the first set of elongated electrical conductors.

266. A Probe Assembly, according to claim 261, wherein:
the third plurality of elongated resilient electrical conductors are electrically interconnected to contact locations on the first surface of the first space transformer.

267. A Probe Assembly, according to claim 261, further including:
a dielectric material disposed on the first surface of the space transformer enveloping a part of the third plurality of elongated resilient electrical conductors.

268. A Probe Assembly, according to claim 261, wherein:
the first plurality of electrical conductors are composite elongated resilient electrical interconnection elements comprising:
a first enlargement at a first end thereof, a second enlargement at a second end thereof; and
a wire interconnecting the first enlargement and the second enlargement.

269. A Probe Assembly, according to claim 261, wherein:
the second plurality of electrical conductors are composite elongated resilient electrical interconnection elements comprising:
a first enlargement at a first end thereof, a second enlargement at a second end thereof; and
a wire interconnecting the first enlargement and the second enlargement.

270. A Probe Assembly, according to claim 261, wherein:
the third plurality of elongated resilient electrical conductors are composite electrical interconnection elements comprising:
a first enlargement at a first end thereof, a second enlargement at a second end thereof; and
a wire interconnecting the first enlargement and the second enlargement.

271. A Probe Assembly, according to claim 261, wherein:
one or more of the first plurality of electrical conductors are an elongated resilient composite structure comprising an elongated element and a coating.

272. A Probe Assembly, according to claim 261, wherein:
one or more of the second plurality of electrical conductors are an elongated resilient composite structure comprising an elongated element and a coating.

273. A structure, according to claim 261, further comprising:
a clamp for holding the first space transformer in place with respect to said second space transformer,
the clamp comprises a sheet of material supported by a member perpendicularly disposed with respect to the second space transformer;
means for affixing the sheet to the member; and
means for urging the first space transformer towards the first surface of the second space transformer.

274. A Probe Assembly, according to claim 273, wherein said clamps comprises a sheet made of aluminum.

275. A Probe Assembly, according to claim 273, wherein the means for urging the first space transformer comprises:
the sheet of material; and
a screw holding the sheet in place with respect to the member and the second space transformer with the first space transformer captured therebetween.

276. A Probe Assembly, according to claim 275, wherein:
said sheet comprises aluminum.

277. A Probe Assembly, according to claim 275, further comprising:
a member perpendicularly disposed with respect to the second space transformer for supporting the sheet of material.

278. A Probe Assembly, according to claim 275, wherein the clamp comprises means for affixing a sheet of material supported by a member perpendicularly dispired with respect to the second space transformer, the sheet is held in place to the member by a screw forming the clamp to hold the first space transformer in place with respect to the second space transformer.

279. A Probe Assembly, according to claim 275, wherein:
the sheet and the member are made of aluminum.

280. A Probe Assembly, according to claim 261, further comprising:
means for aligning of the first space transformer relative to the second space transformer.

281. A Probe Assembly, according to claim 280, wherein the means for aligning the first space transformer comprises:
a plurality of pins disposed on the first space transformer.

282. A Probe Assembly, according to claim 280, wherein the means for aligning the first space transformer comprises:
a plurality of projections for mating with grooves on the interconnection structure.

283. A Probe Assembly, according to claim 261, wherein:
the contact locations are disposed at a first pitch on the second surface of the second space transformer;
the third plurality of elongated resilient electrical conductors are disposed at a second pitch on the first surface of the second space transformer.

284. A Probe Assembly, according to claim 283, wherein:
the first pitch is greater than the second pitch.

285. A Probe Assembly, according to claim 261, wherein:
the first plurality of elongated resilient electrical conductors are disposed at a first pitch on the first surface of the interconnection structure;
the second plurality of elongated resilient electrical conductors are disposed at a second pitch on the second surface of the interconnection structure.

286. A Probe Assembly, according to claim 261, wherein:
the contact locations are disposed at a first pitch on the second surface of the first space transformer;
the third plurality of elongated resilient electrical conductors are disposed at a second pitch on the first surface of the second space transformer;
the first plurality of elongated resilient electrical conductors are disposed at the first pitch on the first surface of the interconnection structure;
the second plurality of elongated resilient electrical conductors are disposed at the first pitch on the second surface of the interconnection structure.

287. A Probe Assembly, according to claim 286, wherein the first pitch is greater than the second pitch.

288. A Probe Assembly, according to claim 261, wherein at least some of the elongated resilient electrical conductors comprise:
a composite interconnection element having an end; and
a protuberance disposed at the end of the composite interconnection element.

289. A structure, according to claim 261, wherein:
the third plurality of elongated resilient electrical conductors are electrically interconnected to contact locations on the first surface of the first space transformer.

290. A structure, comprising:
a first space transformer having a first surface, a second surface, a plurality of contact locations disposed on the second surface thereof, and a plurality of elongated electrical conductors connected to the first surface thereof, said first space transformer adapted in use such that ends of the plurality of elongated electrical conductors for making pressure contacts with a corresponding plurality of contact locations on a semiconductor wafer; and
an interconnection structure having a first surface, a second surface, a first plurality of electrical conductors extending from the first surface thereof, said electrical interconnection structure adapted in use such that contact regions of the first plurality of electrical conductors make pressure connections with the plurality of contact locations on the second surface of the first space transformer, the electrical interconnection structure having a second plurality of electrical conductors extending from the second surface thereof, said interconnection structure adapted in use for contact locations of the second plurality of electrical conductors making pressure connections with a plurality of contact locations on a second space transformer.

291. A structure, according to claim 290, wherein:
said interconnection structure comprises a dielectric material comprising a plurality of elongated electrical conductors embedded therein, a plurality of first ends of which comprise the first plurality of electrical conductors and a plurality of second ends of which comprise the second plurality of electrical conductors.

292. A structure, according to claim 290, wherein:
the contact locations are disposed at a first pitch on the second surface of the first space transformer;
the plurality of elongated electrical conductors are disposed at a second pitch on the first surface of the first space transformer.

293. A structure, according to claim 292, wherein said first pitch is greater than said second pitch.

294. A structure, according to claim 290, wherein:
the second plurality of elongated resilient electrical conductors are disposed at a first pitch on the second surface of the interconnection structure;
the first plurality of elongated resilient electrical conductors are disposed at a second pitch on the first surface of the interconnection structure.

295. A structure according to claim 294, wherein the first pitch is substantially the same as the second pitch.

296. A structure, according to claim 290, wherein:
the contact locations are disposed at a first pitch on the second surface of the space transformer;
the plurality of elongated resilient electrical conductors are disposed at a second pitch on the first surface of the space transformer;
the second plurality of elongated resilient electrical conductors are disposed at the first pitch on the second surface of the electrical interconnection structure;
the first plurality of elongated resilient electrical conductors are disposed at the first pitch on the first surface of the electrical interconnection structure.

297. A structure according to claim 296, wherein the first pitch is greater than the second pitch.

298. A Probe Card Assembly, comprising:
a second space transformer having a first surface, a second surface and a plurality of second contact locations on the first surface thereof;
a first space transformer having a first surface, a second surface, a plurality of first contact locations disposed on the second surface thereof, and a first plurality of elongated resilient electrical conductors mounted adjacent to and extending from the first surface thereof;
wherein the plurality of first contact locations are connected to the plurality of second contact locations of the second space transformer.

299. A Probe Card Assembly, according to claim 298, wherein:
the first plurality of elongated resilient electrical conductors are mounted directly to contact locations on the first surface of the first space transformer.

300. A Probe Card Assembly, according to claim 298, wherein:
the first plurality of elongated resilient electrical conductors are connected to contact locations on the first surface of the first space transformer.

301. A Probe Card Assembly, according to claim 298, wherein:
the first plurality of elongated resilient electrical conductors are composite interconnection elements.

302. A Probe Card Assembly, according to claim 298, further comprising:
means for aligning the first space transformer relative to the second space transformer.

303. A Probe Card Assembly, according to claim 302, wherein the means for aligning the first space transformer comprises:
a plurality of pins disposed on the first space transformer.

304. A Probe Card Assembly, according to claim 302, wherein the means for aligning the first space transformer comprises:
a plurality of engaging projections and grooves.

305. A Probe Card Assembly, according to claim 298, wherein:
the contact locations are disposed at a first pitch on the second surface of the first space transformer;
the first plurality of elongated resilient electrical conductors each having a second end, the second ends of the elongated electrical conductors are at an angle with respect to the first end of the elongated electrical conductor and the contact location, the angle being between a minimum and a maximum value, the second ends are disposed at a second pitch as determined by the angles corresponding to the first plurality of elongated resilient electrical conductors; and
the first pitch is a shortest distance between any two adjacent contact pads and the second pitch is a shortest distance between any two adjacent elongate electrical conductors.

306. A Probe Card Assembly, comprising:
a second space transformer having a first surface, a second surface and a plurality of second contact locations on the first surface thereof;
a first space transformer having a first surface, a second surface, a plurality of first contact locations disposed on the second surface thereof, and a first plurality of elongated electrical conductors electrically connected adjacent to and extending from the first surface thereof;
wherein the plurality of first contact locations are connected to the plurality of second contact locations of the second substrate.

307. A Probe Card Assembly, according to claim 306, wherein:
the first plurality of elongated electrical conductors are electrically interconnected to contact locations on the first surface of the first space transformer.

308. A Probe Card Assembly, according to claim 306, wherein:
the first plurality of elongated electrical conductors are electrically interconnected to contact locations on the first surface of the first space transformer.

309. A Probe Card Assembly, according to claim 306, wherein:
the first plurality of elongated electrical conductors are composite interconnection elements.

310. A Probe Card Assembly, according to claim 306, further comprising:
means for aligning the first space transformer relative to the second space transformer.

311. A Probe Card Assembly, according to claim 310, wherein the means for aligning the first space transformer comprises:
a plurality of pins disposed on the first space transformer.

312. A Probe Card Assembly, according to claim 310, wherein the means for aligning the first space transformer comprises:
a plurality of engaging projections and grooves.

313. A Probe Card Assembly, according to claim 306, wherein:
the contact locations are disposed at a first pitch on the second surface of the space transformer;
the first plurality of elongated electrical conductors each having a second end, the second end of the elongated electrical conductors are at an angle with respect to the first end of the elongated electrical conductor and the contact location, the angle being between a minimum and a maximum value, the second ends are disposed at a second pitch as determined by the angles corresponding to the first and second elongated electrical conductors; and
the first pitch is a shortest distance between any two adjacent contact pads and the second pitch is a shortest distance between any two adjacent elongated electrical conductors.

314. A Probe Assembly, according to claim 285, wherein the first pitch is substantially the same as the second pitch.

315. A Probe Assembly, according to claim 202, wherein:
the interconnection structure comprises a dielectric material comprising a plurality of elongated electrical conductors embedded therein:
a plurality of first ends of which comprise the first plurality of elongated resilient electrical conductors and a plurality of second ends of which comprise the second plurality of elongated resilient electrical conductors.

316. A structure, according to claim 291, wherein the plurality of first ends comprise a first plurality of elongated resilient electrical conductors and the plurality of second ends comprise a second plurality of elongated resilient electrical conductors.

317. A structure, according to claim 262, wherein the plurality of first ends comprise a first plurality of elongated resilient electrical conductors and the plurality of second ends comprise a second plurality of elongated resilient electrical conductors.

318. A space transformer comprising:
a first substrate provided with first electrical contact locations on one side thereof;
first elongated electrical conductors, each having an elongate flexible shape and a respective first end connected to a respective first electrical contact location of said first electrical contact locations, and extending from the respective first electrical contact location;
a second substrate provided with second electrical contact locations on one side thereof and third electrical contact locations on an opposite side thereof;
the second contact locations facing the first contact locations and each first elongated electrical conductor having a respective second end connected to a respective one of the second electrical contact locations, the second substrate being disassembleable from the first substrate; and
second elongated electrical conductors, each having an elongate flexible shape and a respective first end connected to a respective third electrical contact location of said third electrical contact locations and extending from the respective third electrical contact location,
selected ones of the first elongated electrical conductors are interconnected with selected ones of the second contact locations, and
selected ones of the first contact locations are spaced from one another by first distances, and selected ones of the second elongated electrical conductors have second ends, removely located from the first ends thereof, which are spaced from one another by second distances.

319. A space transformer, according to claim 318, wherein:
the first substrate is a printed circuit board.

320. A space transformer, according to claim 318, wherein:
selected ones of the second electrical contact locations and selected ones of the third electrical contact locations are electrically interconnected by electrically conductive vias.

321. A space transformer, according to claim 318, wherein selected ones of the first flexible elongated electrical conductors comprise:
a flexible elongate core element having a first end and a second end and formed of a readily-shaped material;
an electrically conductive coating, formed of a layer of conductive material disposed on the elongate core element.

322. A space transformer, according to claim 321, wherein:
the flexible elongate core element is selected from the group consisting of:
palladium, gold alloy, copper alloy, gold, aluminum, copper, silver, nickel and combinations thereof.

323. A space transformer, according to claim 321, wherein:
the flexible elongate core element has a diameter in the range of from 1 to 5 mils.

324. A space transformer, according to claim 323, wherein:
the flexible elongate core element is a wire.

325. A space transformer, according to claim 321, wherein:
the flexible elongate core element has a length of about 40 mils.

326. A space transformer, according to claim 321, wherein:
the electrically conductive coating comprising a material selected from the group consisting of Au, Cr, Co, Ni and Pd.

327. A space transformer, according to claim 321, wherein:
the electrically conductive coating comprises nickel and cobalt.

328. A space transformer, according to claim 321, wherein:
the electrically conductive coating comprises a coating selected from the group consisting of nickel, cobalt, chromium, gold and palladium.

329. A space transformer, according to claim 321, wherein:
the electrically conductive coating is formed of a material selected from nickel, cobalt, chromium and gold.

330. A space transformer, according to claim 321, wherein:
the electrically conductive coating is a coating selected from the group consisting of an electroplated coating, an electrolessly plated coating, a sputtered coating and an e-beam evaporated coating.

331. A space transformer, according to claim 330, wherein:
the electrically conductive coating is a thin layer.

332. A space transformer, according to claim 318, wherein:
the substrate is a multi-layer interconnection substrate.

333. A space transformer, according to claim 318, wherein:
the first substrate comprises a dielectric material comprising a plurality of elongated electrical conductors embedded therein; and
a plurality of first ends of which comprise the first plurality of electrical conductors.

334. A space transformer comprising:
a first substrate comprising on one side thereof first elongated electrical conductors, each having an elongate flexible shape and a respective first end disposed at the one side thereof, and extending therefrom;
a second substrate provided with second electrical contact locations on one side thereof and third electrical contact locations on an opposite side thereof;
the second contact locations facing the first contact locations and each first elongated electrical conductor having a respective second end connected to a respective one of the second electrical contact locations, the second substrate being disassembleable from the first substrate; and
second elongated electrical conductors, each having an elongate flexible shape and a respective first end connected to a respective third electrical contact location of said third electrical contact locations and extending from the respective third electrical contact location,
selected ones of the first elongated electrical conductors are interconnected with selected ones of the second contact locations, and
selected ones of the first contact locations are spaced from one another by first distances, and selected ones of the second elongated electrical conductors have second ends, remotely located from the first ends thereof, which are spaced from one another by second distances.

335. A space transformer, according to claim 318, wherein the second distance is different than the first distance.

336. A space transformer, according to claim 318, wherein the second substrate is a printed circuit card.

337. A space transformer, according to claim 336, wherein:
the first substrate comprises a dielectric material comprising a plurality of elongated electrical conductors embedded therein;
a plurality of first ends of which comprise the first plurality of electrical conductors.

338. A space transformer, according to claim 334, wherein:
the first substrate is a printed circuit board.

339. A space transformer, according to claim 334, wherein:
selected ones of the second electrical contact locations and selected ones of the third electrical contact locations are electrically interconnected by electrically conductive vias.

340. A space transformer, according to claim 335, wherein selected ones of the first flexible elongated electrical conductors comprise:
a flexible elongate core element having a first end and a second end and formed of a readily-shaped material;
an electrically conductive coating, formed of a layer of conductive material disposed on the elongate core element.

341. A space transformer, according to claim 340, wherein:
the flexible elongate core element is selected from the group consisting of:
palladium, gold alloy, copper alloy, gold, aluminum, copper, silver, nickel and combinations thereof.

342. A space transformer, according to claim 340, wherein:
the flexible elongate core element has a diameter in the range of from 1 to 5 mils.

343. A space transformer, according to claim 342, wherein:
the flexible elongate core element is a wire.

344. A space transformer, according to claim 339, wherein:
the flexible elongate core element has a length of about 40 mils.

345. A space transformer, according to claim 340, wherein:
the electrically conductive coating comprising a material selected from the group consisting of Au, Cr, Co, Ni and Pd.

346. A space transformer, according to claim 340, wherein:
the electrically conductive coating comprises nickel and cobalt.

347. A space transformer, according to claim 340, wherein:
the electrically conductive coating comprises a coating selected from the group consisting of nickel, cobalt, chromium, gold and palladium.

348. A space transformer, according to claim 340, wherein:
the electrically conductive coating is formed of a material selected from nickel, cobalt, chromium and gold.

349. A space transformer, according to claim 340, wherein:
the electrically conductive coating is a coating selected from the group consisting of an electroplated coating, an electrolessly plated coating, a sputtered coating and an e-beam evaporated coating.

350. A space transformer, according to claim 349, wherein:
the electrically conductive coating is a thin layer.

351. A space transformer, according to claim 335, wherein:
the substrate is a multi-layer interconnection substrate.

352. A space transformer, according to claim 334, wherein:
the first distance is different that the second distance.

353. A space transformer, according to claim 334, wherein:
the second substrate is a printed circuit card.

354. A structure comprising:
a first substrate comprising a surface and a plurality of first elongated flexible electrical conductors extending from locations at the surface;
a second substrate comprising first electrical contact locations on one side thereof and second contact locations on an opposite side thereof;
the first contact location facing the surface of the first substrate, and each first elongated flexible electrical conductor of the first substrate have an end electrically connected to a first contact location, the second substrate being disassembleable from the first substrate, and second elongated flexible conductors having a first end electrically connected to a second contact location and extending away therefrom;
selected ones of the first elongated electrical conductors are electrically interconnected with selected ones of the first contact locations;
the first contact locations are spaced apart from one another by a first distance, the second locations are spaced apart from one another by a second distance.

355. A structure, according to claim 354, wherein:
the second distance is different than the first distance.

356. A structure, according to claim 354, wherein:
the second substrate is a printed circuit card.

357. A structure, according to claim 354, wherein:
the first substrate comprises a dielectric material comprising the first plurality of elongated electrical conductors embedded therein;
a plurality of first ends of which comprise the first plurality of electrical conductors.

358. A structure, according to claim 354, wherein:
the first substrate is a printed circuit board.

359. A structure, according to claim 354, wherein:
selected ones of the first electrical contact locations and selected ones of the second electrical contact locations are electrically interconnected by electrically conductive vias.

360. A structure, according to claim 354, wherein selected ones of the first flexible elongated electrical conductors comprise:
a flexible elongate core element having a first end and a second end and formed of a readily-shaped material;
an electrically conductive coating, formed of a layer of conductive material disposed on the elongate core element.

361. A structure, according to claim 360, wherein:
the flexible elongate core element is selected from the group consisting of:
palladium, gold alloy, copper alloy, gold, aluminum, copper, silver, nickel and combinations thereof.

362. A structure, according to claim 360, wherein:
the flexible elongate core element has a diameter in the range of from 1 to 5 mils.

363. A structure, according to claim 362, wherein:
the flexible elongate core element is a wire.

364. A structure, according to claim 360, wherein:
the flexible elongate core element has a length of about 40 mils.

365. A structure, according to claim 360, wherein:
the electrically conductive coating comprising a material selected from the group consisting of Au, Cr, Co, Ni and Pd.

366. A structure, according to claim 360, wherein:
the electrically conductive coating comprises nickel and cobalt.

367. A structure, according to claim 360, wherein:
the electrically conductive coating comprises a coating selected from the group consisting of nickel, cobalt, chromium, gold and palladium.

368. A structure, according to claim 360, wherein:
the electrically conductive coating is formed of a material selected from nickel, cobalt, chromium and gold.

369. A structure, according to claim 360, wherein:
the electrically conductive coating is a coating selected from the group consisting of an electroplated coating, an electrolessly plated coating, a sputtered coating and an e-beam evaporated coating.

370. A structure, according to claim 369, wherein:
the electrically conductive coating is a thin layer.

371. (Amended 1st) A structure, according to claim 355, wherein:
the second substrate is a multi-layer interconnection substrate.

372. (Amended 1st) A structure, according to claim 355, wherein:
the elongated electrical conductor extending from the locations of the surface of the first substrate comprises a wire.

373. A structure comprising:
a first substrate comprising first electrical contact locations and a plurality of first elongated flexible electrical conductors extending from the first electrical contact locations;
a second substrate comprising second electrical contact locations on one side thereof and third contact locations on an opposite side thereof;
the second contact location facing the first contact locations, and each first elongated flexible electrical conductor comprises an end electrically connected to a first contact location, the second substrate being disassembleable from the first substrate, and second elongated flexible conductors having a first end electrically connected to a second contact location and extending away therefrom;
selected ones of the first elongated electrical conductors are electrically interconnected with selected ones of the second contact locations;
the first contact locations are spaced apart from one another by a first distance, the second contact locations are spaced apart from one another by a second distance.

374. A structure, according to claim 373, wherein:
the second distance is different than the first distance.

375. A structure, according to claim 373, wherein:
the second substrate comprises a printed circuit card.

376. A structure, according to claim 373, wherein:
selected elements of the first and second plurality of elongated electrical conductors are embedded in a dielectric material.

377. A structure, according to claim 373, wherein:
the first substrate is a printed circuit board.

378. A structure, according to claim 373, wherein:
selected ones of the second electrical contact locations and selected ones of the third electrical contact locations are electrically interconnected by electrically conductive vias.

379. A structure, according to claim 373, wherein an element selected from the group consisting of selected ones of the first and second flexible elongated electrical conductors comprise:
a flexible elongate core element having a first end and a second end and formed of a readily-shaped material;
an electrically conductive coating, formed of a layer of conductive material disposed on the elongate core element.

380. A structure, according to claim 379, wherein:
the flexible elongate core element is selected from the group consisting of:
palladium, gold alloy, copper alloy, gold, aluminum, copper, silver, nickel and combinations thereof.

381. A structure, according to claim 379, wherein:
the flexible elongate core element has a diameter in the range of from about 1 to 5 mils.

382. A structure, according to claim 381, wherein:
the flexible elongate core element is a wire.

383. A structure, according to claim 379, wherein:
the flexible elongate core element has a length of about 40 mils.

384. A structure, according to claim 379, wherein:
the electrically conductive coating comprising a material selected from the group consisting of Au, Cr, Co, Ni and Pd.

385. A structure, according to claim 379, wherein:
the electrically conductive coating comprises nickel and cobalt.

386. A structure, according to claim 379, wherein:
the electrically conductive coating comprises a coating selected from the group consisting of nickel, cobalt, chromium, gold and palladium.

387. A structure, according to claim 379, wherein:
the electrically conductive coating is formed of a material selected from nickel, cobalt, chromium and gold.

388. A structure, according to claim 379, wherein:
the electrically conductive coating is a coating selected from the group consisting of an electroplated coating, an electrolessly plated coated, a sputtered coating and an e-beam evaporated coating.

389. A structure, according to claim 388, wherein:
the electrically conductive coating is a thin layer.

390. A structure, according to claim 373, wherein:
an element selected from the group consisting of the first and the second substrate is a multi-layer interconnection substrate.

391. A structure, according to claim 373, wherein:
the second substrate comprises a fan out substrate.

392. A structure, according to claim 373, wherein:
the first and second elongated electrical conductors are embedded in a dielectric layer and the second substrate is a fan out substrate.
